(19) United States
(12) Patent Application Publication
(10) Pub. No.: US 2007/0257305 A1
(43) Pub. Date: Nov. 8, 2007

(54) NONVOLATILE SEMICONDUCTOR MEMORY DEVICE AND MANUFACTURING METHOD THEREOF

(76) Inventors: Yoshitaka SASAGO, Tachikawa (JP); Tomoyuki Ishi, Kokubunji (JP); Toshiyuki Mine, Fussa (JP); Taro Osabe, Tokyo (JP)

Correspondence Address: MILES & STOCKBRIDGE PC, 1751 PINNACLE DRIVE, SUITE 500, MCLEAN, VA, 22102-3833, US

(21) Appl. No.: 11/740,799

(22) Filed: Apr. 26, 2007

(30) Foreign Application Priority Data
May 1, 2006 (JP) JP 2006-127406

(51) Int. Cl. H01L 29/788

(52) U.S. Cl. 257/316

(57) ABSTRACT

By decreasing the threshold voltage shift due to the potential change of the cells adjacent in a word line direction, the reliability of a flash memory can be enhanced. Memory cells of a flash memory are formed in p-type wells of a semiconductor substrate and include gate insulator films, floating gates, high-K insulator films, and control gates (word lines). The floating gates and control gates (word lines) are isolated by high-K insulator films. The plurality of memory cells arrayed in row a direction are isolated by isolation trenches extending in a column direction. In the isolation trenches, a silicon oxide film is embedded. In the silicon oxide film, an air gap is provided. A lower end of the air gap extends near to the bottom of the isolation trench, and its upper end extends further above the upper surface of the high-K insulator film covering the floating gate.

### CROSS-REFERENCE TO RELATED APPLICATION

The present application claims priority from Japanese Patent Application No. JP 2006-127406 filed on May 1, 2006, the content of which is hereby incorporated by reference into this application.

### TECHNICAL FIELD OF THE INVENTION

The present invention relates to a semiconductor device and a manufacturing method thereof. More particularly, it relates to a technology effectively applied to achieve the high integration density and performance improvement in a semiconductor device having an electrically programmable nonvolatile memory.

### BACKGROUND OF THE INVENTION

Of the electrically programmable nonvolatile memories, a flash memory is known as the bulk erasable one. The flash memory is excellent in portability and impact resistance, and can be electrically erased in bulk. Therefore, its demand as a memory device for small portable information devices such as a mobile personal computer and a digital still camera has been rapidly expanding in recent years. For the expansion of the market thereof, the reduction of bit cost by the reduction of memory cell area is an important element, and various memory cells for realizing the same have been proposed.

For example, International Electron Devices Meeting, 2003, pp. 823-826 (Non-Patent Document 1) discloses a structure of AND type cell array which is a kind of contactless type cell suited to large capacity, in which a third gate is provided in a memory cell in addition to a floating gate and a control gate, and an inversion layer which is formed by the potential applied to the third gate on the surface of a semiconductor substrate below the third gate is used as a local bit line. Further, examples of the so-called NAND type flash memory which is also a kind of contactless type cell suited to large capacity are reported in International Electron Devices Meeting, 2004, pp. 873-876 (Non-Patent Document 2), Solid-State Circuits Conference, 2005, pp. 44-45 (Non-Patent Document 3) and Solid-State Circuits Conference, 2005, pp. 46-47 (Non-Patent Document 4). Furthermore, Japanese Patent Application Laid-Open Publication No. 2005-101066 (Patent Document 1) discloses a memory cell structure similar to NAND type flash memory, in which two control gates are coupled to one floating gate. When these memory cell structures are used, the physical area of a memory cell can be reduced to about 4F2 (F: minimum feature size), and thus, the increase of the capacity of the flash memory can be realized.

In these flash memories, the floating gate is designed to have a three-dimensional shape, and the area of an insulator film interposed between the floating gate and the control gate. By this means, the sufficient coupling ratio is secured, and the high-speed programming/erasing characteristic is realized.

In particular, many proposals relate to the structure in which the control gate is embedded between floating gates mutually adjacent in an extending direction of a word line with interposing an insulator film therebetween. In such a structure, since a capacitance between a floating gate and a control gate is formed also on the side surface of the floating gate, a high coupling ratio can be obtained. Also, since the floating gates mutually adjacent in an extending direction of a word line are electrostatically shielded by the control gate, the capacitance between the floating gates is reduced. Accordingly, the phenomenon (threshold voltage shift) where the change of potential of a certain memory cell (threshold voltage state) varies the threshold voltage of its adjacent memory cell can be decreased. Therefore, the reliability of the memory cell can be enhanced.

However, when the space between the floating gates mutually adjacent in an extending direction of a word line becomes narrower due to the reduction of the memory cell size, it is difficult in the above-described structures to embed the control gate in this space with interposing an insulator film. Therefore, it is hard to maintain the sufficient coupling ratio and decrease the threshold voltage shift.

Symp. on VLSI Technology, 2005, pp. 208-209 (Non-Patent Document 5) discloses a technology for securing a sufficient capacitance between a floating gate and a control gate by interposing an insulator film with high dielectric constant (high-K insulator film) between the floating gate and the control gate even if the space between the floating gates mutually adjacent in an extending direction of a word line is narrow.

Japanese Patent Application Laid-Open Publication No. 2004-281662 (Patent Document 2) indicates that, in the case where an insulator film having not so high dielectric constant such as ONO film is used between the floating gate and the control gate, along with the reduction of a memory cell size, there occur the problem that leakage current is increased and the problem that the ratio (C2/C1) of capacitance (C2) between a floating gate and a control gate and capacitance (C1) between a semiconductor substrate and the floating gate is varied. For its solution, the Patent Document 2 proposes a gate structure comprising: a semiconductor substrate provided with a convex portion having a first side surface defined by a trench; a first insulator film formed on the convex portion and having a first side surface matched with the first side surface of the convex portion; a first conductor film formed on the first insulator film and having a first side surface matched with the first side surface of the first insulator film; a second insulator film formed on the first conductor film and having a first side surface matched with the first side surface of the first conductor film; and a second conductor film formed on the second insulator film and having a first side surface matched with the first side surface of the second insulator film, wherein the second insulator film has a dielectric film having a dielectric constant higher than the first insulator film, and at least a third insulator film formed in the trench is provided.

### SUMMARY OF THE INVENTION

Prior to the present invention, the inventors of the present invention have examined the case where the cell with a conventional structure is miniaturized and the capacitance between a floating gate and a control gate is acquired only on the upper surface of the floating gate, and a high-K insulator film is used between the floating gate and the control gate in order to secure the sufficient capacitance. FIG. 81 schematically shows the sectional structure of the examined memory cell.

Two memory cells (MC₁, MC₂) adjacent in an extending direction of a word line are isolated by an isolation trench 51 formed in a semiconductor substrate 50. A silicon oxide film 52 is embedded in the isolation trench 51. Each of the memory cells (MC₁, MC₂) has a gate insulator film 53 formed on a surface of the semiconductor substrate 50 and a floating gate 54 formed on the gate insulator film 53. Further, a control gate 56 (word lines WL) is formed on the floating gates 54 via a high-K insulator film 55. In this memory cell structure, since the high-K insulator film 55 is interposed between the floating gate 54 and the control gate 56, the capacitance between the floating gate and control gate is increased.

In the memory cells, however, not only the capacitance between a floating gate and a control gate but also the capacitance between floating gates mutually adjacent in an extending direction of a word line are increased. This is because, since the high-K insulator film 55 is coupled between the two floating gates 54 mutually adjacent in an extending direction of a word line, the capacitance between the floating gates (C_{fg-fg}) via a silicon oxide film 52 in the isolation trench 51 and the fringe capacitance (C_{fringe}) via the high-K insulator film 55 become the actual capacitance between floating gates.

As a result, in the memory cells, when reading data from a selected memory cell (for example, MC₁), the threshold voltage shift applied to the memory cell (MC₁) by the change of a threshold voltage state of an adjacent memory cell (for example, MC₂) is rather increased, and problems which lower the reliability of the memory cells such as miss-reading occur.

An object of the present invention is to improve the reliability of a flash memory by decreasing the threshold voltage change caused by the change of potential (threshold voltage state) of a memory cell adjacent in a word line direction to reduce the miss-reading.

The above and other objects and novel characteristics of the present invention will be apparent from the description of this specification and the accompanying drawings.

The typical ones of the inventions disclosed in this application will be briefly described as follows.

A semiconductor device according to the present invention comprises: a plurality of memory cells disposed in a matrix in a first direction of a main surface of a semiconductor substrate of a first conductivity type and in a second direction orthogonal to the first direction, wherein each of the plurality of memory cells includes a floating gate formed on the main surface of the semiconductor substrate via a gate insulator film, a first insulator film formed on the floating gate, and a control gate formed on the floating gate via the first insulator film, the plurality of memory cells arrayed in the first direction are mutually isolated by isolation trenches formed in the main surface of the semiconductor substrate and extending in the second direction, the plurality of memory cells arrayed in the second direction are connected in series, the control gates of the plurality of memory cells arrayed in the first direction are integrated to form word lines extending in the first direction, and a second insulator film having an air gap therein is formed in a region where the floating gates adjacent in the first direction are mutually opposed.

Further, a manufacturing method of a semiconductor device according to the present invention comprises: (a) a step of forming the gate insulator film on the main surface of the semiconductor substrate, and forming a first conductor film, a first insulator film, a second conductor film, and a third insulator film on the gate insulator film; (b) a step of patterning the third insulator film, the second conductor film, the first insulator film, and the first conductor film, thereby forming a first stacked member which covers the surface of the semiconductor substrate in the memory cell forming region and extends in the second direction and exposing the semiconductor substrate surface in an isolation region; (c) a step of etching the semiconductor substrate in the isolation region with using the first stacked member as a mask, thereby forming a trench extending in the second direction; (d) a step of depositing a second insulator film to cover the first stacked member on the semiconductor substrate and embedding the second insulator film incompletely in the trench, thereby forming an isolation trench embedded with the second insulator film having an air gap therein; (e) after the step (d), etching back the second insulator film to expose an upper surface of the third insulator film, and then removing the third insulator film to expose an upper surface of the second conductor film; and (f) after the step (e), a step of forming a third conductor film on the semiconductor substrate and patterning the third conductor film, the second conductor film, the first insulator film, and the first conductor film, thereby forming the control gate formed of the third conductor film and the second conductor film and forming the floating gate formed of the first conductor film.

The effects obtained by typical aspects of the present invention will be briefly described below.

The reliability of a semiconductor device having an electrically programmable nonvolatile memory can be enhanced. At the same time, high-speed programming/erasing characteristic can be realized.

### BRIEF DESCRIPTIONS OF THE DRAWINGS

FIG. 1 is a plan view showing the principal part of a semiconductor device according to a first embodiment of the present invention;

FIG. 2 is a sectional view taken along the line A-A in FIG. 1;

FIG. 3 is a sectional view taken along the line B-B in FIG. 1;

FIG. 4 is a sectional view taken along the line C-C in FIG. 1;

FIG. 5 is a sectional view taken along the line D-D in FIG. 1;

FIG. 6 is a sectional view taken along the line E-E in FIG. 1;

FIG. 7 is a circuit diagram for describing the reading operation of a semiconductor device according to the first embodiment of the present invention;

FIG. 8 is a circuit diagram for describing the programming operation of a semiconductor device according to the first embodiment of the present invention;

FIG. 9 is a circuit diagram for describing the erasing operation of a semiconductor device according to the first embodiment of the present invention;

FIG. 10 is a sectional view showing the principal part of the manufacturing method of a semiconductor device according to the first embodiment of the present invention;

FIG. 11 is a sectional view showing the principal part of the manufacturing method of a semiconductor device subsequent to FIG. 10;

FIG. 12 is a sectional view showing the principal part of the manufacturing method of a semiconductor device subsequent to FIG. 11;

FIG. 13 is a sectional view showing the principal part of the manufacturing method of a semiconductor device subsequent to FIG. 12;

FIG. 14 is a sectional view showing the principal part of the manufacturing method of a semiconductor device subsequent to FIG. 13;

FIG. 15 is a sectional view showing the principal part of the manufacturing method of a semiconductor device subsequent to FIG. 14;

FIG. 16 is a sectional view showing the principal part of the manufacturing method of a semiconductor device subsequent to FIG. 15;

FIG. 17 is a sectional view showing the principal part of the manufacturing method of a semiconductor device subsequent to FIG. 16;

FIG. 18 is a sectional view showing the principal part of the manufacturing method of a semiconductor device subsequent to FIG. 16;

FIG. 19 is a sectional view showing the principal part of the manufacturing method of a semiconductor device subsequent to FIG. 16;

FIG. 20 is a sectional view showing the principal part of the manufacturing method of a semiconductor device subsequent to FIG. 16;

FIG. 21 is a sectional view showing the principal part of the manufacturing method of a semiconductor device subsequent to FIG. 17 to FIG. 20;

FIG. 22 is a sectional view showing the principal part of the manufacturing method of a semiconductor device subsequent to FIG. 17 to FIG. 20;

FIG. 23 is a sectional view showing the principal part of the manufacturing method of a semiconductor device subsequent to FIG. 21 and FIG. 22;

FIG. 24 is a sectional view showing the principal part of the manufacturing method of a semiconductor device subsequent to FIG. 21 and FIG. 22;

FIG. 25 is a sectional view showing the principal part of the manufacturing method of a semiconductor device subsequent to FIG. 23 and FIG. 24;

FIG. 26 is a sectional view showing the principal part of the manufacturing method of a semiconductor device subsequent to FIG. 23 and FIG. 24;

FIG. 27 is a diagram schematically showing a sectional structure of a memory cell according to the first embodiment;

FIG. 28 is a graph for comparing the relations between the memory size and the threshold voltage shift in the conventional memory cell and the memory cell of the first embodiment;

FIG. 29 is a plan view showing the principal part of a semiconductor device according to a second embodiment of the present invention;

FIG. 30 is a sectional view taken along the line A-A in FIG. 29;

FIG. 31 is a sectional view taken along the line B-B in FIG. 29;

FIG. 32 is a sectional view taken along the line C-C in FIG. 29;

FIG. 33 is a sectional view taken along the line D-D in FIG. 29;

FIG. 34 is a sectional view taken along the line E-E in FIG. 29;

FIG. 35 is a circuit diagram for describing the reading operation of a semiconductor device according to the second embodiment of the present invention;

FIG. 36 is a circuit diagram for describing the programming operation of a semiconductor device according to the second embodiment of the present invention;

FIG. 37 is a circuit diagram for describing the erasing operation of a semiconductor device according to the second embodiment of the present invention;

FIG. 38 is a sectional view showing the principal part of the manufacturing method of a semiconductor device according to the second embodiment of the present invention;

FIG. 39 is a sectional view showing the principal part of the manufacturing method of a semiconductor device subsequent to FIG. 38;

FIG. 40 is a sectional view showing the principal part of the manufacturing method of a semiconductor device subsequent to FIG. 39;

FIG. 41 is a sectional view showing the principal part of the manufacturing method of a semiconductor device subsequent to FIG. 40;

FIG. 42 is a sectional view showing the principal part of the manufacturing method of a semiconductor device subsequent to FIG. 40;

FIG. 43 is a sectional view showing the principal part of the manufacturing method of a semiconductor device subsequent to FIG. 41 and FIG. 42;

FIG. 44 is a sectional view showing the principal part of the manufacturing method of a semiconductor device subsequent to FIG. 41 and FIG. 42;

FIG. 45 is a sectional view showing the principal part of the manufacturing method of a semiconductor device subsequent to FIG. 43 and FIG. 44;

FIG. 46 is a sectional view showing the principal part of the manufacturing method of a semiconductor device subsequent to FIG. 43 and FIG. 44;

FIG. 47 is a sectional view showing the principal part of the manufacturing method of a semiconductor device subsequent to FIG. 45 and FIG. 46;

FIG. 48 is a sectional view showing the principal part of the manufacturing method of a semiconductor device subsequent to FIG. 45 and FIG. 46;

FIG. 49 is a sectional view showing the principal part of the manufacturing method of a semiconductor device subsequent to FIG. 47 and FIG. 48;

FIG. 50 is a sectional view showing the principal part of the manufacturing method of a semiconductor device subsequent to FIG. 47 and FIG. 48;

FIG. 51 is a sectional view showing the principal part of the manufacturing method of a semiconductor device subsequent to FIG. 49 and FIG. 50;

FIG. 52 is a sectional view showing the principal part of the manufacturing method of a semiconductor device subsequent to FIG. 49 and FIG. 50;

FIG. 53 is a plan view showing the principal part of a semiconductor device according to a third embodiment of the present invention;

FIG. 54 is a sectional view taken along the line A-A in FIG. 53;

FIG. 55 is a sectional view taken along the line B-B in FIG. 53;

FIG. 56 is a sectional view taken along the line C-C in FIG. 53;

FIG. 57 is a sectional view taken along the line D-D in FIG. 53;

FIG. 58 is a circuit diagram for describing the reading operation of a semiconductor device according to the third embodiment of the present invention;

FIG. 59 is a circuit diagram for describing the programming operation of a semiconductor device according to the third embodiment of the present invention;

FIG. 60 is a circuit diagram for describing the erasing operation of a semiconductor device according to the third embodiment of the present invention;

FIG. 61 is a sectional view showing the principal part of the manufacturing method of a semiconductor device according to the third embodiment of the present invention;

FIG. 62 is a sectional view showing the principal part of the manufacturing method of a semiconductor device subsequent to FIG. 61;

FIG. 63 is a sectional view showing the principal part of the manufacturing method of a semiconductor device subsequent to FIG. 62;

FIG. 64 is a sectional view showing the principal part of the manufacturing method of a semiconductor device subsequent to FIG. 63;

FIG. 65 is a sectional view showing the principal part of the manufacturing method of a semiconductor device subsequent to FIG. 64;

FIG. 66 is a sectional view showing the principal part of the manufacturing method of a semiconductor device subsequent to FIG. 65;

FIG. 67 is a sectional view showing the principal part of the manufacturing method of a semiconductor device subsequent to FIG. 66;

FIG. 68 is a sectional view showing the principal part of the manufacturing method of a semiconductor device subsequent to FIG. 67;

FIG. 69 is a sectional view showing the principal part of the manufacturing method of a semiconductor device subsequent to FIG. 67;

FIG. 70 is a sectional view showing the principal part of the manufacturing method of a semiconductor device subsequent to FIG. 68 and FIG. 69;

FIG. 71 is a sectional view showing the principal part of the manufacturing method of a semiconductor device subsequent to FIG. 68 and FIG. 69;

FIG. 72 is a sectional view showing the principal part of the manufacturing method of a semiconductor device subsequent to FIG. 70 and FIG. 71;

FIG. 73 is a sectional view showing the principal part of the manufacturing method of a semiconductor device subsequent to FIG. 70 and FIG. 71;

FIG. 74 is a sectional view showing the principal part of the manufacturing method of a semiconductor device subsequent to FIG. 72 and FIG. 73;

FIG. 75 is a sectional view showing the principal part of the manufacturing method of a semiconductor device subsequent to FIG. 72 and FIG. 73;

FIG. 76 is a sectional view showing the principal part of the manufacturing method of a semiconductor device subsequent to FIG. 74 and FIG. 75;

FIG. 77 is a sectional view showing the principal part of the manufacturing method of a semiconductor device subsequent to FIG. 74 and FIG. 75;

FIG. 78 is a sectional view showing the principal part of the manufacturing method of a semiconductor device subsequent to FIG. 76 and FIG. 77;

FIG. 79 is a sectional view showing the principal part of the manufacturing method of a semiconductor device subsequent to FIG. 76 and FIG. 77;

FIG. 80 is a sectional view showing the principal part of a semiconductor device according to a fourth embodiment of the present invention; and

FIG. 81 is a diagram schematically showing a sectional structure of a conventional flash memory.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

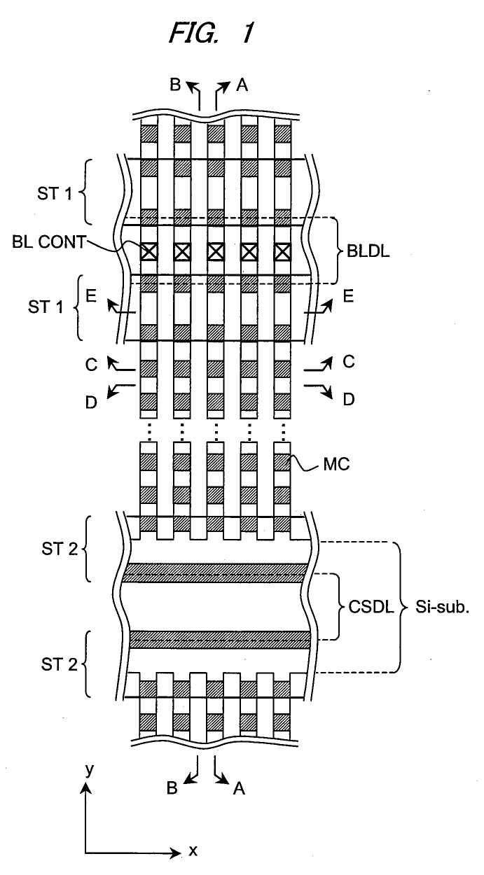

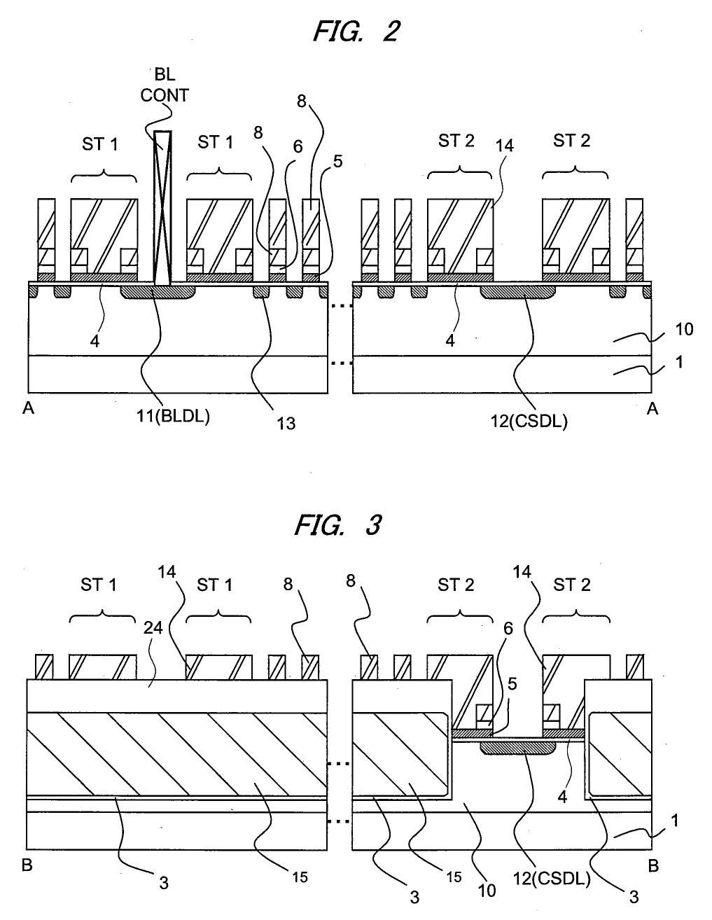

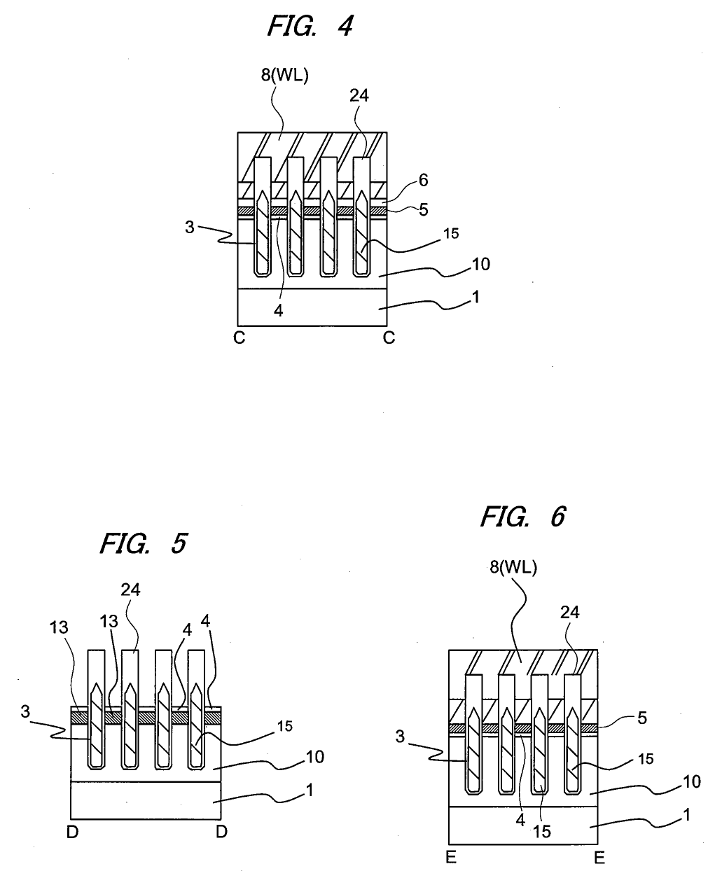

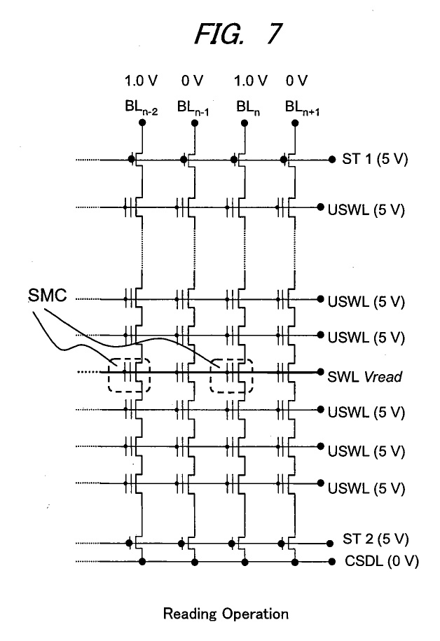

FIG. 1 is a plan view showing the principal part of a memory array region of a semiconductor device according to a first embodiment of the present invention, FIG. 2 to FIG. 6 are sectional views taken along the line A-A, the line B-B, the line C-C, the line D-D, and the line E-E in FIG. 1, respectively, and FIG. 7 to FIG. 9 are circuit diagrams for describing the operation of the semiconductor device according to the first embodiment of the present invention. In FIG. 1, the illustration of some members is omitted so as to make the structure of the memory array region easy to see.

The semiconductor device of this embodiment is a NAND type flash memory. Memory cells are formed on p-type wells 10 in a semiconductor substrate (hereinafter, referred to as substrate) 1 made of p-type single crystal silicon and include gate insulator films (tunnel insulator films) 4, floating gates 5, high-K insulator films 6, control gates 8, and n-type diffusion layers 13 (source, drain). The control gates 8 are integrated and extend in a row direction (x direction in FIG. 1), and form the word lines WL. The p-type well 10 and the floating gate 5 are isolated by the gate insulator film 4, and the floating gate 5 and the control gate 8 (word lines WL) are isolated by the high-K insulator film 6.

In the memory array region of the substrate 1, a plurality of memory cells having the above configuration are disposed in a matrix in the row direction and the column direction (y direction in FIG. 1). The plurality of memory cells arrayed in the row direction, that is, in the extending direction of the word line WL are mutually isolated by isolation trenches 3 having an elongated belt-like planar shape extending in the column direction. Meanwhile, the plurality of memory cells arrayed in the column direction are connected in series via respective n-type diffusion layers 13 (source, drain).

The plurality of memory cells arrayed in the column direction are connected to a select transistor ST₁ at one end of the memory array region and connected to bit line contact (BLCONT) via an n-type diffusion layer 11 (BLDL) of the select transistor ST₁. The bit line contact (BLCONT) is formed in an interlayer insulator film (not shown) on the word line WL, and it is connected to the bit line BL (FIG. 7 to FIG. 9) composed of metal wiring formed on the interlayer insulator film. Further, the plurality of memory cells extending in the column direction are connected to an n-type diffusion layer 12 of a select transistor ST₂ at the other end of the memory array region. The n-type diffusion layer 12 of the select transistor ST₂ forms a common source line (CSDL).

A silicon oxide film 24 is embedded in the isolation trench 3. The silicon oxide film 24 embedded in the isolation trench 3 partly protrudes upward from the opening of the isolation trench 3, and its upper end further extends above the upper surface of the high-K insulator film 6 covering the floating gate 5. Further, an air gap 15 is provided in the silicon oxide film 24 embedded in the isolation trench 3. The lower end of the air gap 15 extends near to the bottom of the isolation trench 3, and its upper end extends above the upper surface of the high-K insulator film 6 covering the floating gate 5.

Next, the operation of NAND type flash memory will be described. First, in the reading operation, as shown in FIG. 7, 1 V is applied to bit lines (BLₙ, BLₙ₋₁) connected to a selected memory cell (SMC), about 5 V is applied to select transistors (ST₁, ST₂), about 5 V is applied to unselected word line (USWL), 0 V is applied to common source line (CSDL), and 0 V is applied to the p-type well 10, respectively. Further, read verification voltage (Vread) is applied to the selected word line (SWL) to verify ON or OFF of the selected memory cell (SMC).

The programming is performed to the plurality of memory cells connected to selected word line (SWL) by using Fowler-Nordheim tunnel current via the tunnel insulator film 4. In this case, of the plurality of memory cells connected to the selected word line (SWL), the memory cells where the programming is performed and the memory cells where it is not performed are distinguished and controlled depending on the magnitude of voltages applied to bit lines.

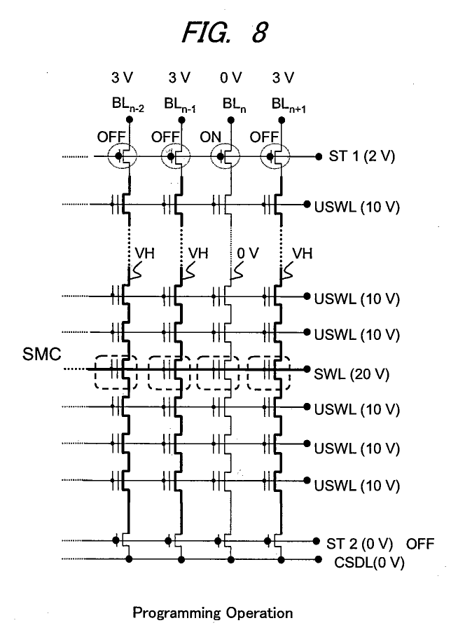

At the time of programming operation, as shown in FIG. 8, about 2 V is applied to the select transistor (ST₁), 0 V is applied to bit line (BLₙ) connected to the selected memory cell (SMC), and about 3 V is applied to other bit lines. Further, 0 V is applied to the common source line (CSDL), the select transistor (ST₂), and the p-type well 10. In this state, the potential of the unselected word line (USWL) is increased rapidly from 0 V to about 10 V (in about several microseconds or less). As a result, the potential of the floating gate 5 below the unselected word line (USWL) is increased, and consequently the potential of the substrate surface below the memory cell is about to increase. At this time, since the select transistor (ST₁) connected to the bit line to which a voltage of about 3 V is applied is in an off state, the potential of the substrate surface below the memory cell is increased (VH). On the other hand, since the select transistor (ST₁) connected to the bit line (BLₙ) to which 0 V is applied is in an on state, electrons are supplied to the substrate surface below the memory cell from the bit line contract (BLCONT) side, and its potential becomes 0 V.

Subsequently, the potential of the selected word line (SWL) is increased from 0 V to about 20 V. At this time, in the bit line (BLₙ) where the substrate surface potential is 0 V, a large potential difference occurs between the floating gate and the substrate surface, and electrons are injected into the floating gate 5 from the surface of the substrate 1 by tunnel current, by which the programming occurs. On the other hand, in the bit line where the substrate surface potential is VH, since the potential difference between the floating gate and the substrate surface is decreased, the programming does not occur.

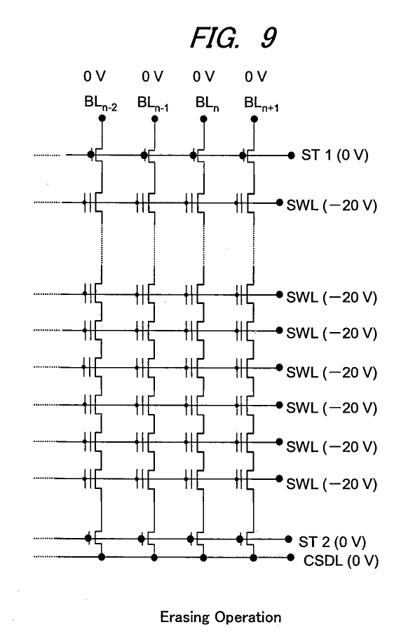

At the time of erasing operation, as shown in FIG. 9, a voltage of about −20 V is applied to all word lines between the select transistors (ST₁, ST₂), and electrons are emitted to the substrate 1 from the floating gate 5 by Fowler-Nordheim tunnel current via the gate insulator film 4.

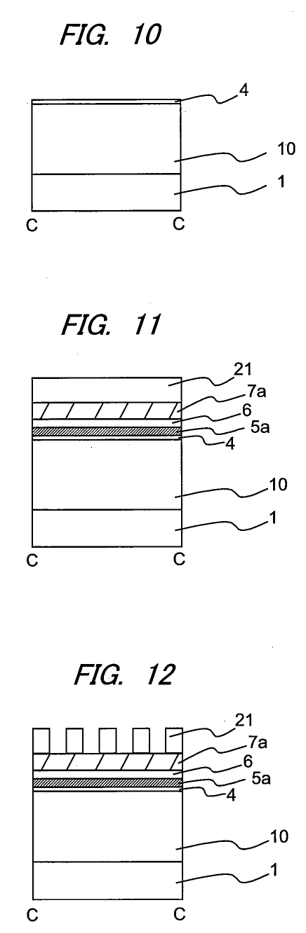

Next, a manufacturing method of the NAND type flash memory will be described with reference to FIG. 10 to FIG. 26. FIG. 10 to FIG. 17 correspond to sectional views of the principal parts taken along the line C-C in FIG. 1.

First, as shown in FIG. 10, after phosphorus ions are implanted into the substrate 1 made of p-type single crystal silicon to form a p-type well 10, a gate insulator film 4 of a silicon oxide film with a thickness of about 9 nm is formed on the surface of the p-type well 10 by thermal oxidation method. Next, as shown in FIG. 11, a polysilicon film 5a doped with phosphorus, a high-K insulator film 6, a polysilicon film 7a doped with phosphorus, and a silicon nitride film 21 are sequentially deposited on the gate insulator film 4 by CVD method. The polysilicon film 5a is a conductor film to be the floating gate 5 in a later process, and its film thickness is about 10 nm. The high-K insulator film 6 is an insulator film for securing the capacitance between the floating gate and the control gate, and it is formed of a metal oxide film with higher dielectric constant than that of silicon oxide such as Al₂O₃, HfSiO, or HfO₂. The polysilicon film 7a is a conductor film formed as a part of the control gate 8 in a later process, and its film thickness is about 50 nm. The film thickness of the silicon nitride film 21 is about 50 nm.

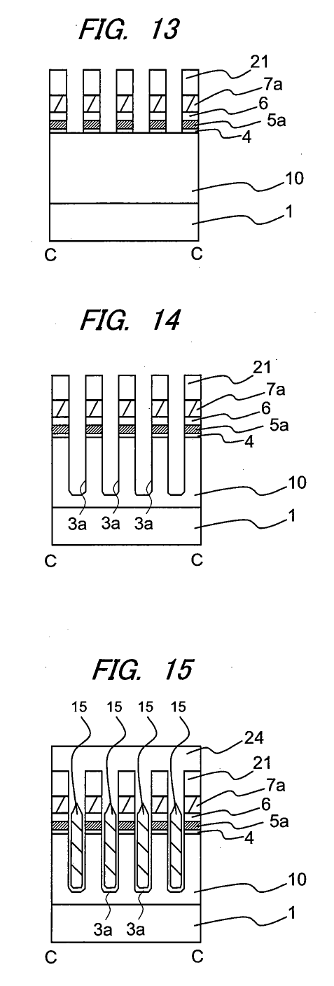

Next, after the silicon nitride film 21 is patterned by dry etching using the photoresist film as a mask as shown in FIG. 12, as shown in FIG. 13, the polysilicon film 7a is dry-etched using the silicon nitride film 21 as a mask, and subsequently the high-K insulator film 6, the polysilicon film 5a, and the gate insulator film 4 are dry-etched. By this means, the surface of the p-type well 10 is partly exposed.

Further, as shown in FIG. 14, by dry-etching the exposed p-type well 10, a plurality of trenches 3a are formed. Thereafter, as shown in FIG. 15, a silicon oxide film 24 is deposited by CVD method. The silicon oxide film 24 is deposited to have a large film thickness so that its upper surface is higher than the upper surface of the silicon nitride film 21. At this time, if the depositing condition of poor coating properties is used, the silicon oxide film 24 is not embedded completely in the trenches 3a. Therefore, air gaps 15 are formed inside the silicon oxide film 24. The air gap 15 is formed at least in a region where the polysilicon films 5a adjacent in row direction are mutually opposed. More preferably, it is formed also in a region where the high-K insulator films 6 covering the polysilicon films 5a are mutually opposed. However, the upper end of the air gap 15 is preferably positioned below the upper surface of the silicon nitride film 21. Through the process described above, the isolation trenches 3 having an elongated belt-like planar shape extending in a column direction (y direction) and arrayed at specific intervals in a row direction (x direction) are completed.

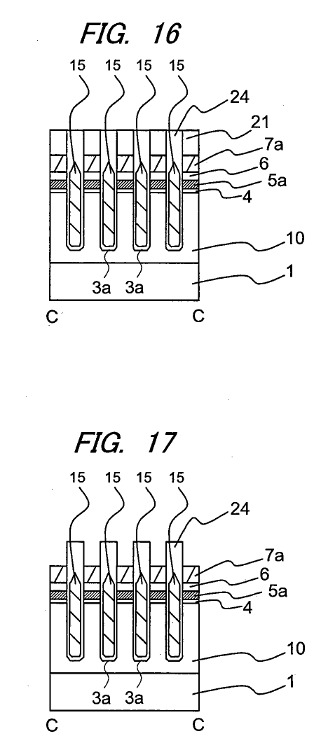

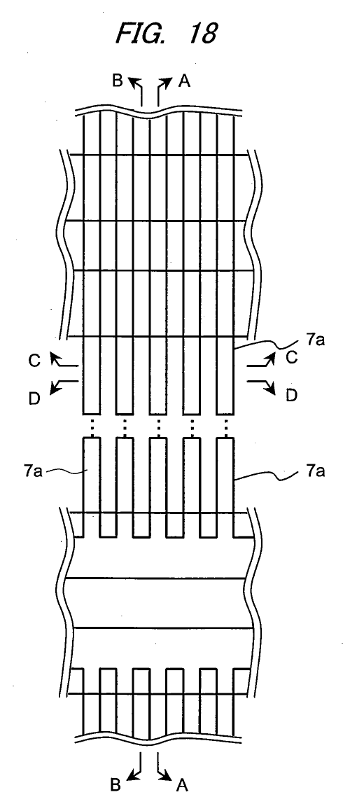

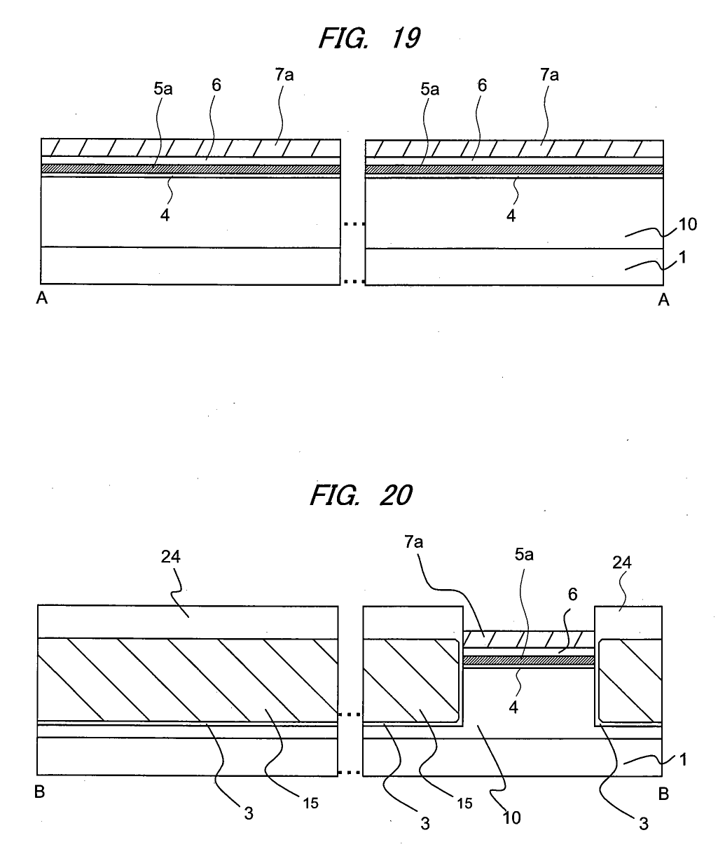

After the upper surface of the silicon nitride film 21 is exposed by etching back the silicon oxide film 24 as shown in FIG. 16, as shown in FIG. 17, the silicon nitride film 21 is removed by dry etching or wet etching, thereby exposing the upper surface of the polysilicon film 7a. FIG. 18 shows the planar shape of the polysilicon films 7a (and underlying high-K insulator films 6 and polysilicon films 5a) formed in the memory array region. The polysilicon films 7a (and underlying high-K insulator films 6 and polysilicon films 5a) have an elongated belt-like planar shape extending in a column direction and cover the part to be active regions of the p-type well 10. FIG. 19 is a sectional view taken along the line A-A in FIG. 1 at this time, and FIG. 20 is a sectional view taken along the line B-B in FIG. 1 at this time. The subsequent process will be described with reference to the A-A sectional view and the B-B sectional view.

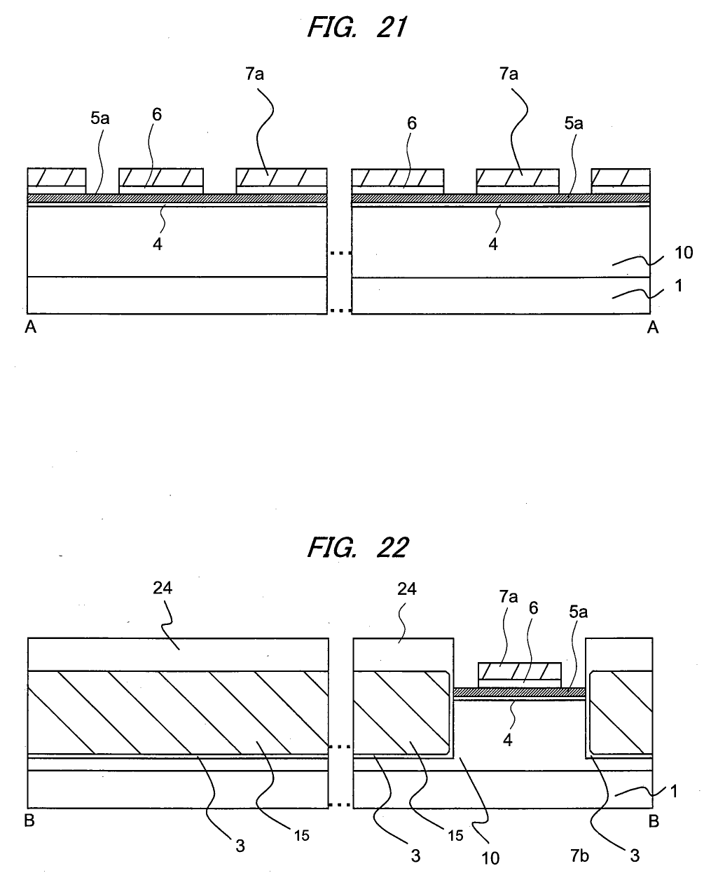

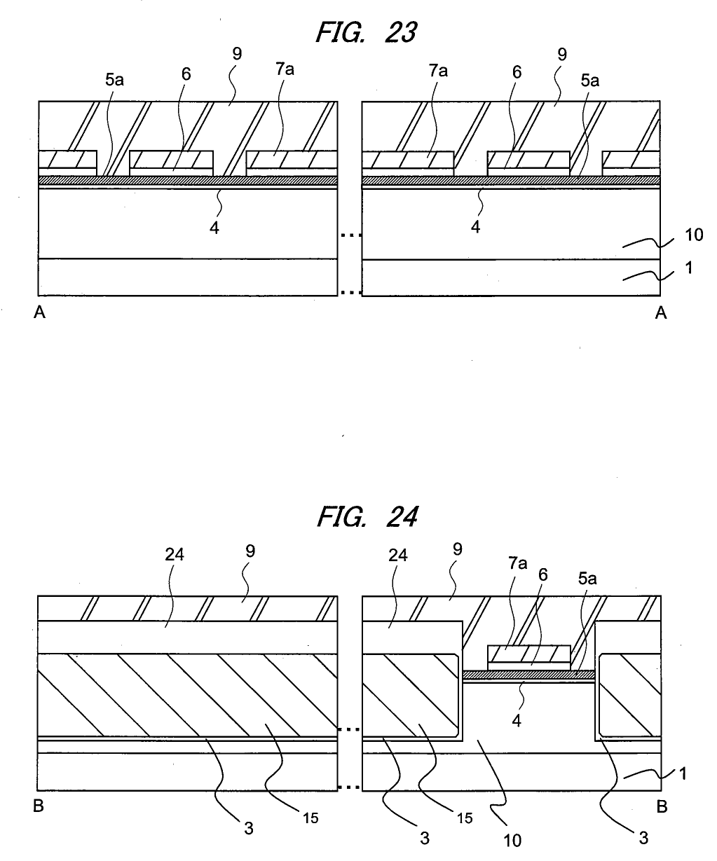

Next, as shown in FIG. 21 and FIG. 22, by patterning the polysilicon film 7a and the high-K insulator film 6 in a region where the select transistors (ST₁, ST₂) are formed in a later process, the polysilicon film 5a is exposed. Next, as shown in FIG. 23 and FIG. 24, a metal film 9 is deposited by sputtering method. The metal film 9 is formed of, for example, a stacked film of a tungsten nitride film and a tungsten film or a metal silicide film such as a tungsten silicide film.

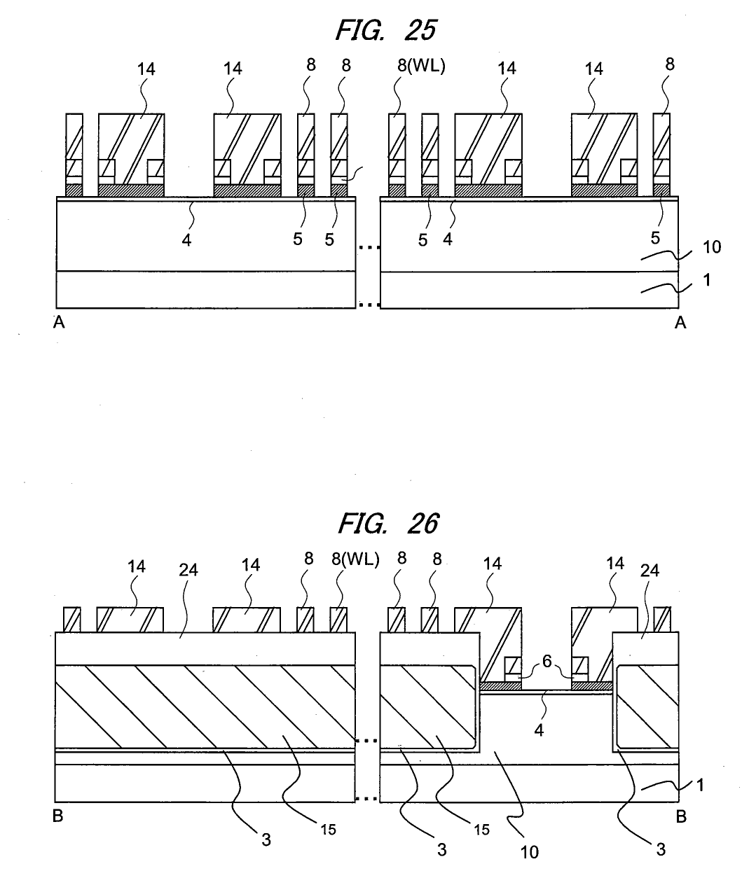

Then, as shown in FIG. 25 and FIG. 26, the polysilicon films 7a, the high-K insulator films 6, and the polysilicon films 5a are patterned using the photoresist film as a mask, the metal film 9. Through the process described above, control gates 8 (word lines WL) composed of a stacked film of the metal films 9 and the polysilicon films 7a are formed, and the floating gates 5 composed of the polysilicon films 5a are formed. Further, at the end of the memory array region, gate electrodes 14 of the select transistors (ST₁, ST₂) composed of the stacked film of the metal films 9 and the polysilicon films 7a and 5a are formed.

Next, by implanting arsenic ions into the p-type well 10 to form the n-type diffusion layers 11, 12, and 13, the memory cells and the select transistors (ST₁, ST₂) shown in FIG. 1 to FIG. 6 are completed. Thereafter, though not shown in the drawing, after an interlayer insulator film is deposited on the control gate 8 (word line WL), the interlayer insulator film is etched to form contact holes reaching the word lines WL, the p-type well 10, the select transistors (ST₁, ST₂), and the n-type diffusion layers 11 and 12. Then, by forming metal wiring on the interlayer insulator film, the NAND type flash memory of this embodiment is completed.

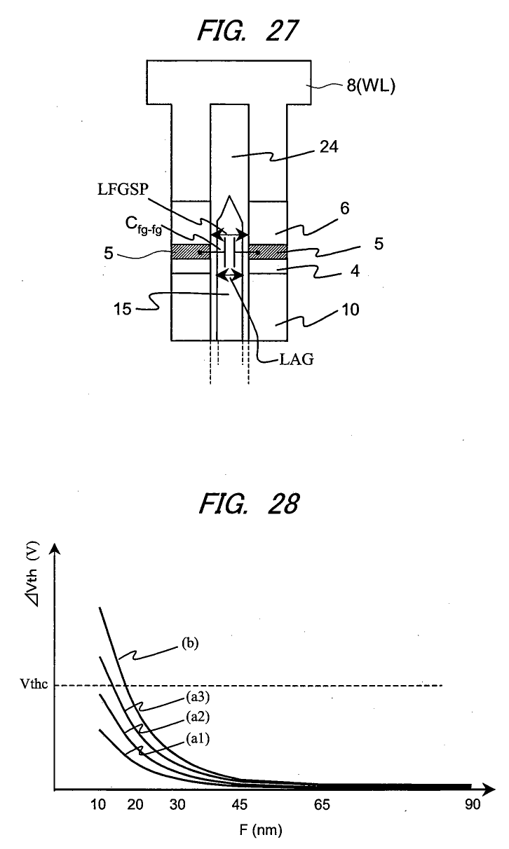

FIG. 27 is a diagram schematically showing the sectional structure of memory cells of this embodiment. In this case, when the reading operation of a memory cell (for example, MC₁) is to be performed, if the threshold voltage shift applied to the memory cell (MC₁) by the change in the threshold voltage state of a memory cell (for example, MC₂) adjacent in the word line direction is set to be ΔVth, the following formulas (1) and (2) are obtained.
ΔVth=C_{fg-fg}/Cₜₒₜ×|Vth_{prog}−Vthₑᵣₐₛₑ| (1)
Cₜₒₜ=(C_{fg-cg}+C_{fg-sub}+C_{fg-fg}+ . . . ) (2)

Herein, C_{fg-fg}, C_{fg-cg}, C_{fg-sub} are the capacitance between the floating gates, the capacitance between the floating gate and the control gate, and the capacitance between the floating gate and the well, respectively. In the formula (2), Cₜₒₜ is the total capacitance around the floating gate where the threshold voltage shift (ΔVth) is caused.

In the conventional memory cell shown in FIG. 81, a silicon oxide film (specific dielectric constant=about 3.9) is embedded in the isolation trench between two floating gates. Meanwhile, in the memory cell of this embodiment, an air gap 15 (specific dielectric constant=about 1.0) with a lower dielectric constant than that of silicon oxide is provided. Further, in the conventional memory cell, the high-K insulator film is coupled between two floating gates. However, in the memory cell of this embodiment, the high-K insulator film 6 is isolated for each memory cell. Therefore, the memory cell of this embodiment is smaller in the capacitance between floating gates in comparison with the conventional memory cell.

The decreasing effect of the threshold voltage shift (ΔVth) is determined by the ratio of the dimension between the floating gates (LFGPS) and the width (LAG) of air gap 15 shown in FIG. 27. Herein, if α=LGA+LFGPS (formula 3), α=0 when there is no air gap 15 (LAG=0), and α=1 when the air gap 15 fills all the space between the floating gates (LAG=LFGPS).

FIG. 28 is a graph for comparing the relations between the memory size and the threshold voltage shift (ΔVth) in the conventional memory cell (b) shown in FIG. 81 and the memory cells of this embodiment (a1, a2, a3). In the diagram, a1 represents the case where α is 1 in formula (3), a2 represents the case where α is 0.5, and a3 represents the case where α is 0. In the memory cells of this embodiment, even if the memory cell size is reduced, the threshold voltage shift (ΔVth) by the capacitance between floating gates can be suppressed below the allowable value (Vthc) In particular, in the cases where the air gap 15 is formed, the decreasing effect of the threshold voltage shift (ΔVth) is extremely larger than that of the case where the air gap 15 is not formed (α=0).

In the flash memory of this embodiment, since the high-K insulator film 6 is interposed between the floating gate 5 and the control gate 8, even if the memory size is reduced, it is possible to suppress the decrease of the capacitance between a floating gate and a control gate. As a result, the coupling ratio can be secured, and high-speed programming/erasing characteristic can be realized.

### Second Embodiment

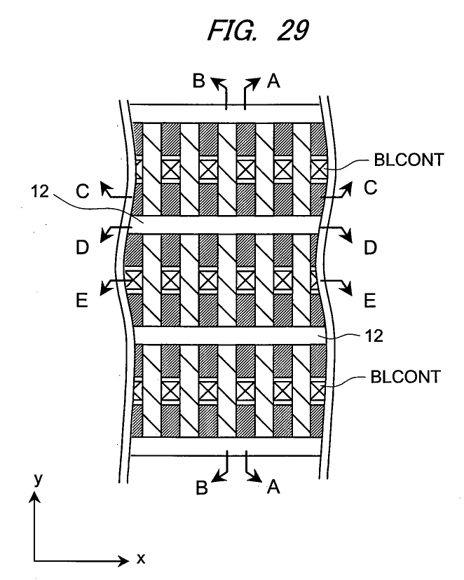

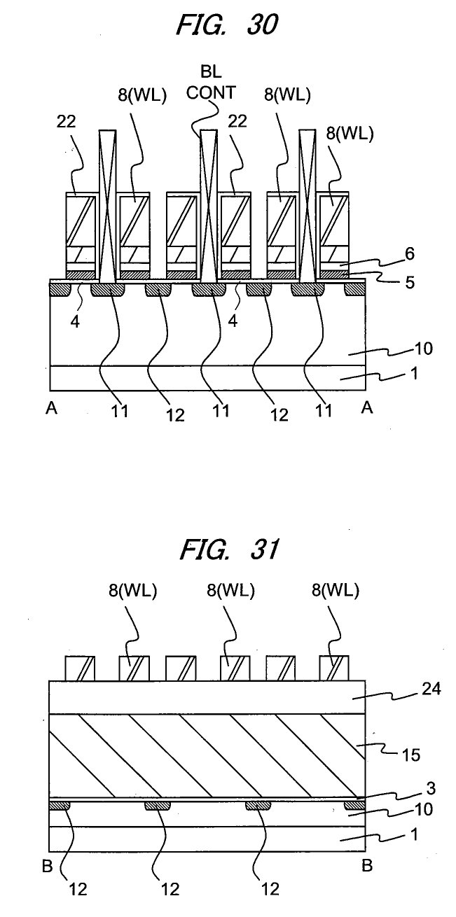

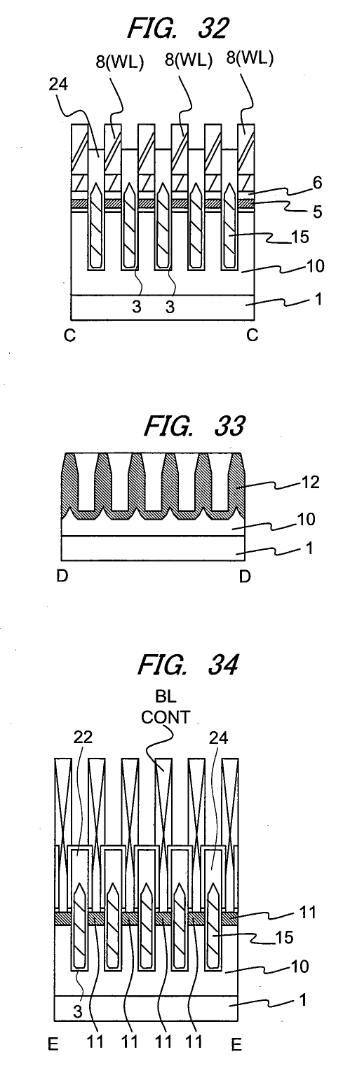

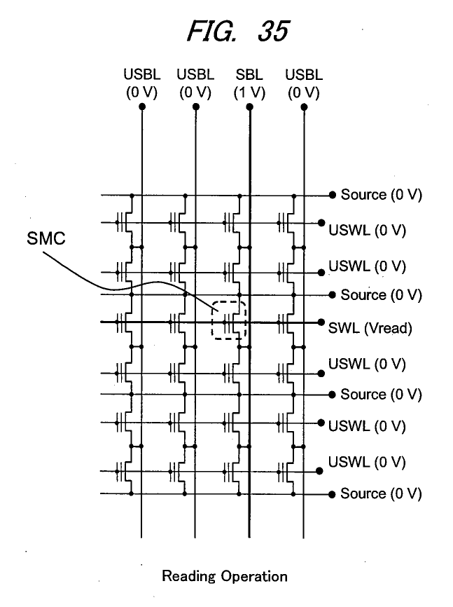

FIG. 29 is a plan view showing the principal part of a memory array region of the semiconductor device according to a second embodiment, FIG. 30 to FIG. 34 are sectional views taken along the line A-A, the line B-B, the line C-C, the line D-D, and the line E-E in FIG. 29, respectively, and FIG. 35 to FIG. 37 are circuit diagrams for describing the operation of the semiconductor device according to the second embodiment. In FIG. 29, the illustration of some members is omitted so as to make the structure of the memory array region easy to see.

The semiconductor device of this embodiment is a flash memory. Memory cells are formed on p-type wells 10 in a semiconductor substrate 1 made of p-type single crystal silicon and include gate insulator films (tunnel insulator films) 4, floating gates 5, high-K insulator films 6, control gates 8, n-type diffusion layers 11 (drain), and n-type diffusion layers 12 (source). The control gates 8 extend in a row direction (x direction in FIG. 29) and form the word lines WL. The p-type well 10 and the floating gate 5 are isolated by the gate insulator film 4, and the floating gate 5 and the control gate 8 (word lines WL) are isolated by the high-K insulator film 6.

In the memory array region of the substrate 1, a plurality of memory cells having the above configuration are disposed in a matrix in the row direction and the column direction (y direction in FIG. 29). The plurality of memory cells arrayed in the row direction, that is, in the extending direction of the word line WL are mutually isolated by isolation trenches 3 having an elongated belt-like planar shape extending in the column direction. Meanwhile, the plurality of memory cells arrayed in the column direction are connected in series via respective n-type diffusion layers 11 (drain) and n-type diffusion layers 12 (source). The n-type diffusion layer 11 (drain) and n-type diffusion layer 12 (source) are commonly used by two memory cells adjacent in the column direction.

A bit line contact (BLCONT) is connected to each of the n-type diffusion layers 11 (drain). The bit line contact (BLCONT) is formed in an interlayer insulator film (not shown) on the word line WL and is connected to the bit line BL (FIG. 35 to FIG. 37) made of metal wiring formed on the interlayer insulator film. As shown in FIG. 33, the n-type diffusion layer 12 (source) of each of the plurality of memory cells arrayed in the column direction is integrated to form a common source line.

Similar to the flash memory of the first embodiment, a silicon oxide film 24 is embedded in the isolation trench 3. The silicon oxide film 24 partly protrudes upward from the opening of the isolation trench 3, and its upper end further extends above the upper surface of the high-K insulator film 6 covering the floating gate 5. Further, an air gap 15 is provided in the silicon oxide film 24. The upper end of the air gap 15 extends above the upper surface of the high-K insulator film 6 covering the floating gate 5.

The operation of the flash memory will be described. First, in the reading operation, as shown in FIG. 35, about 1 V is applied to the bit line (SBL) connected to a selected memory cell (SMC), 0 V is applied to other bit lines (USBL), 0 V is applied to unselected word line (USWL), 0 V is applied to the n-type diffusion layer 12 (source), and 0 V is applied to the p-type well 10, respectively. Further, read verification voltage (Vread) is applied to the selected word line (SWL) to verify ON or OFF of the selected memory cell (SMC).

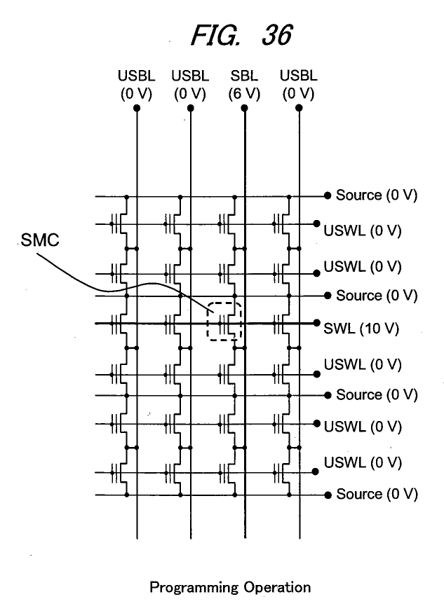

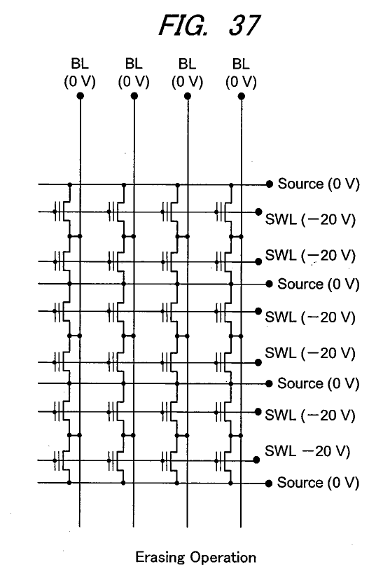

The programming operation is performed by using hot electron injection from the drain side. As shown in FIG. 36, at the time of the programming operation, about 6 V is applied to the bit line (SBL) connected to selected memory cell (SMC), 0 V is applied to other bit lines (USBL), 0 V is applied to the unselected word line (USWL), 0 V is applied to the n-type diffusion layer 12 (source), and 0 V is applied to the p-type well 10. Further, about 10 V is applied to the selected word line (SWL), and hot electrons generated on the n-type diffusion layer 11 (drain) side are injected into the floating gate 5. At the time of erasing operation, as shown in FIG. 37, a voltage of about −20 V is applied to all word lines, and electrons are emitted to the substrate 1 from the floating gate 5 by Fowler-Nordheim tunnel current via the gate insulator film 4.

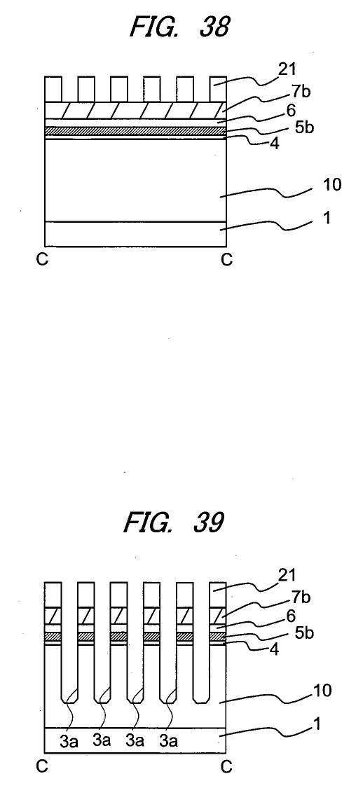

Next, a manufacturing method of the flash memory will be described with reference to FIG. 38 to FIG. 52. FIG. 38 to FIG. 41 correspond to sectional views of the principal part taken along the line C-C in FIG. 29.

First, as shown in FIG. 38, a gate insulator film 4 is formed on the surface of the p-type well 10, and a polysilicon film 5b doped with phosphorus, a high-K insulator film 6, and a polysilicon film 7b doped with phosphorus are sequentially deposited on the gate insulator film 4. Thereafter, a silicon nitride film 21 is deposited on the polysilicon film 7b. The high-K insulator film 6 is formed of a metal oxide film with higher dielectric constant than silicon oxide such as Al₂O₃, HfSiO, or HfO₂.

Next, as shown in FIG. 39, after the polysilicon film 7b, the high-K insulator film 6, and the polysilicon film 5b are dry-etched using the silicon nitride film 21 as a mask, the gate insulator film 4 and the p-type well 10 are dry-etched. By this means, a plurality of trenches 3a are formed in the p-type well 10.

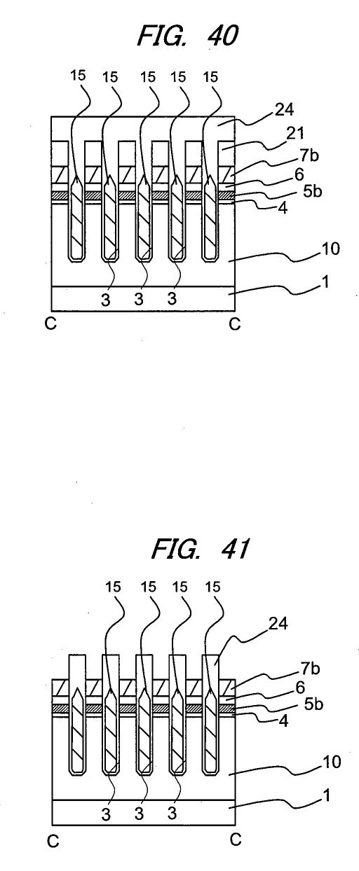

Next, as shown in FIG. 40, a silicon oxide film 24 is deposited by CVD method. At this time, similar to the first embodiment, the silicon oxide film 24 is embedded incompletely in the trenches 3a so that air gaps 15 are formed therein. The depositing condition is controlled so that the upper end of the air gap 15 is higher than the upper surface of the high-K insulator film 6 and lower than the upper surface of the silicon nitride film 21. Through the process described above, the isolation trenches 3 having an elongated belt-like planar shape extending in a column direction and arrayed at specific intervals in a row direction are completed.

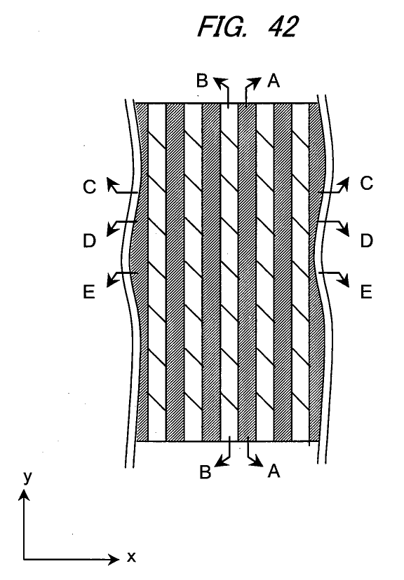

Next, as shown in FIG. 41, after the upper surface of the silicon nitride film 21 is exposed by etching back the silicon oxide film 24, the silicon nitride film 21 is removed by dry etching or wet etching, thereby exposing the upper surface of the polysilicon film 7b. FIG. 42 shows the planar shape of the polysilicon films 7b (and underlying high-K insulator films 6 and polysilicon films 5a) formed in the memory array region. The polysilicon films 7b (and underlying high-K insulator films 6 and polysilicon films 5a) have an elongated belt-like planar shape extending in a column direction and cover the part to be active regions of the substrate 1. The subsequent process will be described with reference to the A-A sectional view, the D-D sectional view, and the E-E sectional view of FIG. 29.

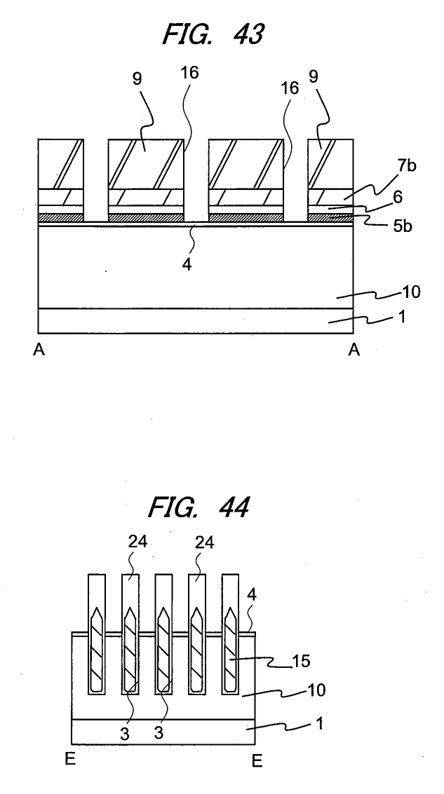

Next, as shown in FIG. 43 and FIG. 44, after a metal film 9 is deposited by sputtering method, openings 16 are formed by dry-etching the metal film 9, the polysilicon film 7b, the high-K insulator film 6, and the polysilicon film 5b in the drain forming region with using the photoresist film as a mask. The metal film 9 is formed of, for example, a stacked film of a tungsten nitride film and a tungsten film or a metal silicide film such as a tungsten silicide film.

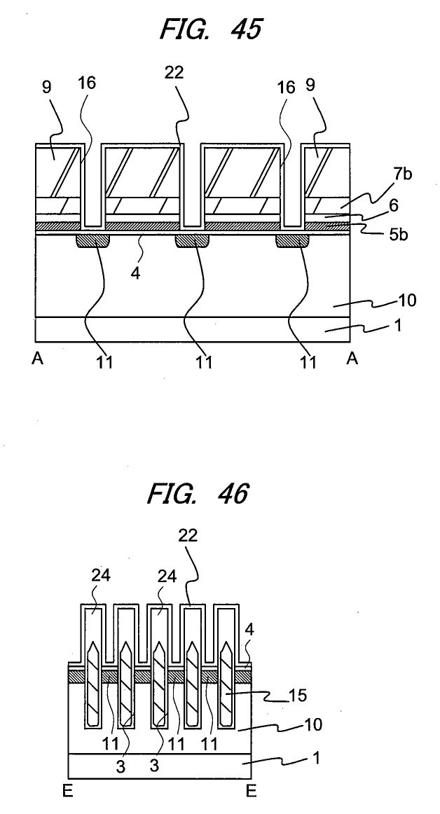

Then, as shown in FIG. 45 and FIG. 46, after arsenic ions are implanted into the p-type well 10 below the openings 16 to form n-type diffusion layers 11 (drain), a silicon nitride film 22 is deposited by CVD method. The silicon nitride film 22 is deposited to have a small thickness so as not to completely embed the openings 16 on the n-type diffusion layers 11 (drain).

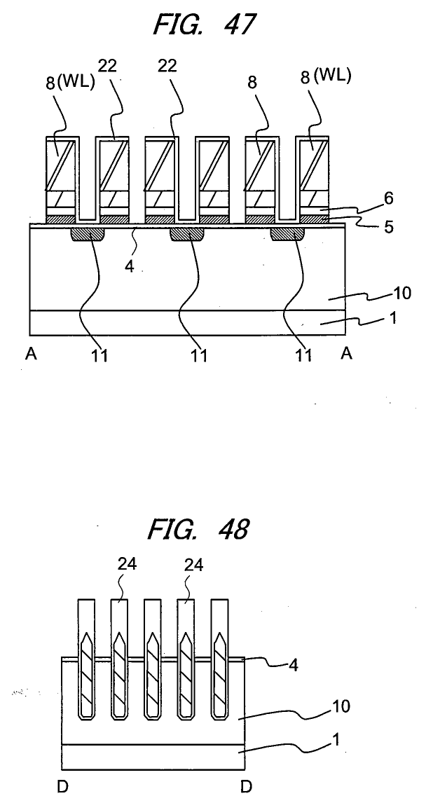

Next, as shown in FIG. 47 and FIG. 48, the silicon nitride film 22, the metal film 9, the polysilicon film 7b, the high-K insulator film 6, and the polysilicon film 5b in the source forming region are dry-etched using the photoresist film as a mask. Through the process described above, the control gate 8 (word line WL) composed of a stacked film of the metal film 9 and the polysilicon film 7b is formed, and the floating gate 5 composed of the polysilicon film 5b is formed.

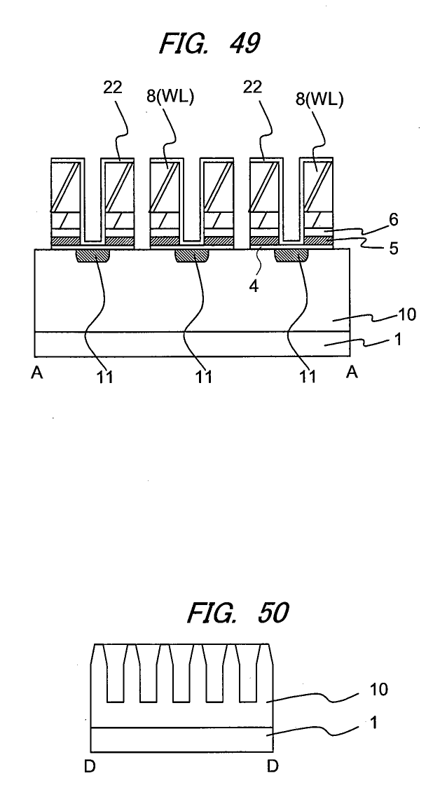

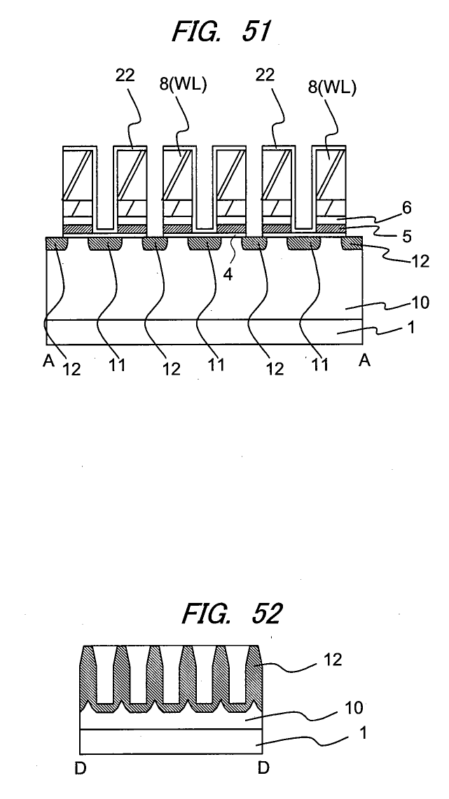

Then, as shown in FIG. 49 and FIG. 50, by dry etching using the photoresist film as a mask, the silicon oxide film 24 embedded in the isolation trenches 3 in the source forming region is removed, and the p-type well 10 is exposed. Subsequently, as shown in FIG. 51 and FIG. 52, arsenic ions are implanted into the p-type well 10 to form the n-type diffusion layer 12 (source). By this means, the memory cell shown in FIG. 29 to FIG. 34 is completed.

Thereafter, though not shown in the drawing, after an interlayer insulator film is deposited, the interlayer insulator film is etched to form contact holes reaching the word lines WL, the p-type well 10, and the n-type diffusion layers 11 and 12, and metal wiring is formed on the interlayer insulator film. By this means, the NAND type flash memory of this embodiment is completed.

Similar to the flash memory in the first embodiment, in the flash memory of this embodiment, air gaps 15 (specific dielectric constant=about 1.0) with a lower dielectric constant than silicon oxide (specific dielectric constant=about 3.9) are present in the isolation trenches 3 between two floating gates 5 adjacent in a row direction, and the high-K insulator film 6 is isolated between the two floating gates 5. Therefore, similar to the flash memory in the first embodiment, even if the memory size is reduced, the threshold voltage shift (ΔVth) due to the capacitance between the floating gates can be suppressed below an allowable value.

Also, similar to the flash memory in the first embodiment, since the high-K insulator film 6 is interposed between the floating gate 5 and the control gate 8 in the flash memory of this embodiment, even if the memory size is reduced, it is possible to suppress the decrease of the capacitance between a floating gate and a control gate. As a result, the coupling ratio can be secured, and high-speed programming/erasing characteristic can be realized.

### Third Embodiment

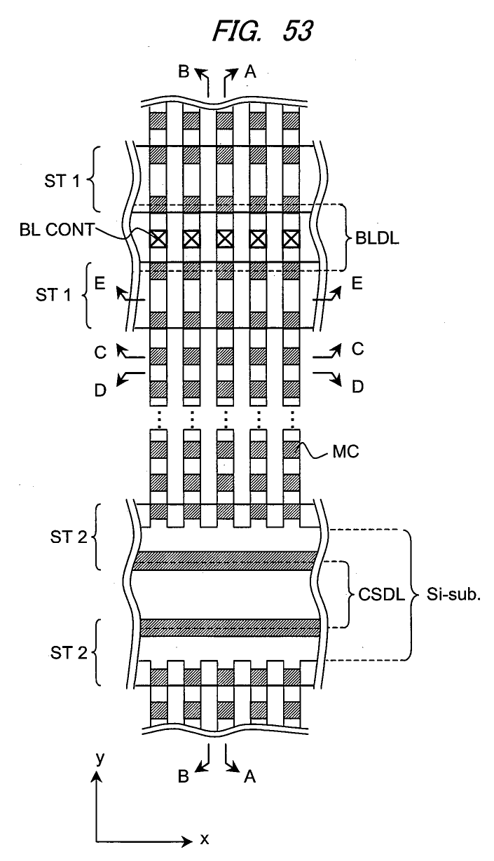

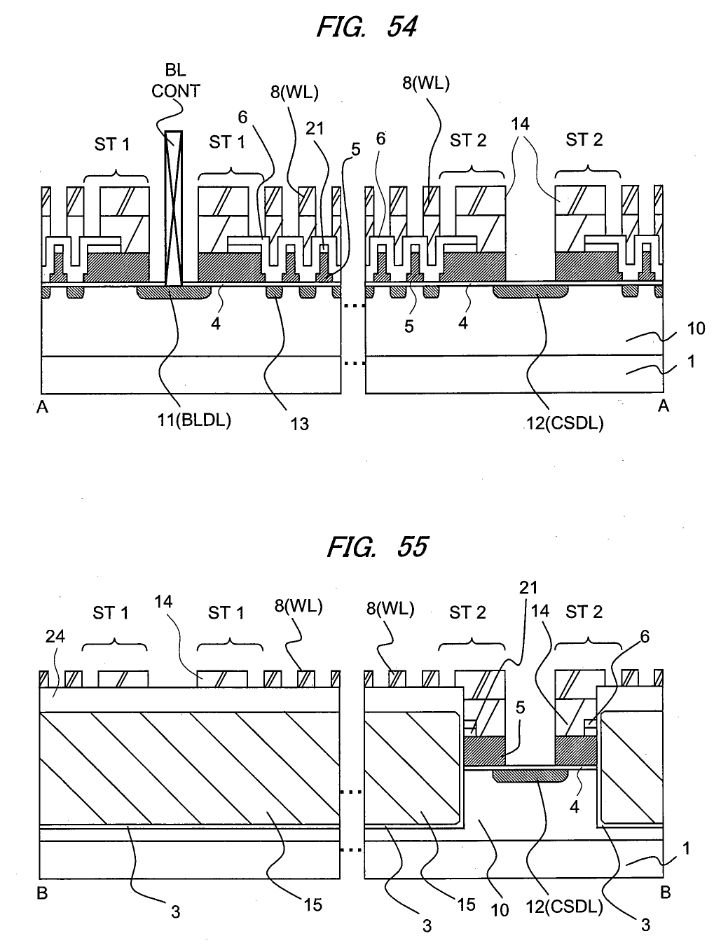

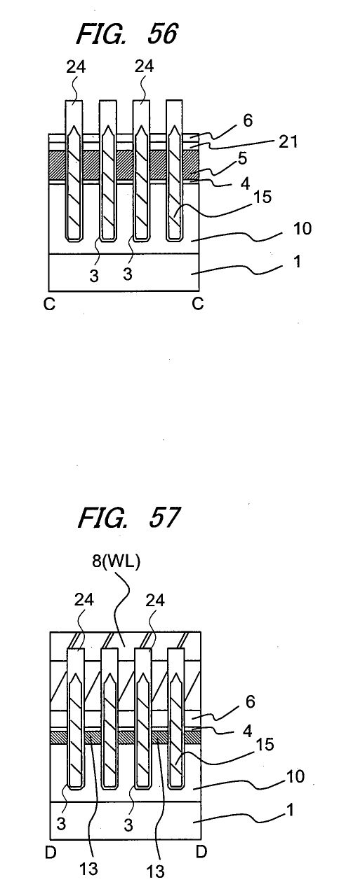

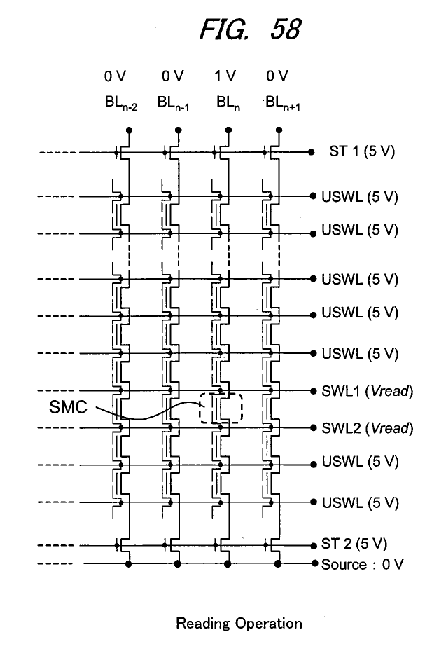

FIG. 53 is a plan view showing the principal part of a memory array region of a semiconductor device according to a third embodiment, FIG. 54 to FIG. 57 are sectional views taken along the line A-A, the line B-B, the line C-C, and the line D-D in FIG. 53, respectively, and FIG. 58 to FIG. 60 are circuit diagrams for describing the operation of the semiconductor device according to the third embodiment. In FIG. 53, the illustration of some members is omitted so as to make the structure of the memory array region easy to see.

The semiconductor device of this embodiment is a NAND type flash memory. Similar to the first embodiment, memory cells are formed on p-type wells 10 in a semiconductor substrate 1 and include gate insulator films (tunnel insulator films) 4, floating gates 5, high-K insulator films 6, control gates 8, and n-type diffusion layers 13 (source, drain). The control gates 8 extend in a row direction (x direction in FIG. 53) and form the word lines WL. The p-type well 10 and the floating gate 5 are isolated by the gate insulator film 4, and the floating gate 5 and the control gate 8 (word lines WL) are isolated by the high-K insulator film 6.

In the memory array region of the substrate 1, a plurality of memory cells having the above configuration are disposed in a matrix in the row direction and the column direction (y direction in FIG. 53). The plurality of memory cells arrayed in the row direction are mutually isolated by isolation trenches 3 having an elongated belt-like planar shape extending in the column direction. Meanwhile, the plurality of memory cells arrayed in the column direction are connected in series via respective n-type diffusion layers 13 (source, drain).

The plurality of memory cells arrayed in the column direction are connected to a select transistor ST₁ at one end of the memory array region and connected to bit line contact (BLCONT) via an n-type diffusion layer 11 (BLDL) of the select transistor ST₁. The bit line contact (BLCONT) is formed in an interlayer insulator film (not shown) on the word line WL, and it is connected to the bit line BL (FIG. 58 to FIG. 60) composed of metal wiring formed on the interlayer insulator film. Further, the memory cells extending in the column direction are connected to an n-type diffusion layer 12 of a select transistor ST₂ at the other end of the memory array region. The n-type diffusion layer 12 of the select transistor ST₂ forms a common source line (CSDL).

Similar to the flash memories of the first and second embodiments, a silicon oxide film 24 is embedded in the isolation trench 3. The silicon oxide film 24 partly protrudes upward from the opening of the isolation trench 3, and its upper end further extends above the upper surface of the high-K insulator film 6 covering the floating gate 5. Further, an air gap 15 is provided in the silicon oxide film 24. The upper end of the air gap 15 extends above the upper surface of the high-K insulator film 6 covering the floating gate 5.

As shown in FIG. 54, in the flash memory of this embodiment, the sectional shape of the floating gate 5 taken along the column direction is an inverted T shape. Also, the control gate 8 (word line WL) is disposed between two floating gates 5 adjacent in the column direction. That is, one memory cell has two control gates 8 (word lines WL).

The operation of NAND type flash memory will be described. First, in the reading operation, as shown in FIG. 58, 1 V is applied to the bit line (BLₙ) connected to a selected memory cell (SMC), about 5 V is applied to select transistors (ST₁, ST₂), about 5 V is applied to unselected word lines (USWL), 0 V is applied to common source line (CSDL), and 0 V is applied to the p-type well 10, respectively. Further, read verification voltage (Vread) is applied to two selected word lines (SWL₁, SWL₂) corresponding to the selected memory cell (SMC) to verify ON or OFF of selected memory cell (SMC).

The programming is performed to the plurality of memory cells connected to the two selected word lines (SWL₁, SWL₂) by using Fowler-Nordheim tunnel current via the tunnel insulator film 4. In this case, of the plurality of memory cells connected to the selected word lines (SWL₁, SWL₂), the memory cells where the programming is performed and the memory cells where it is not performed are distinguished and controlled depending on the magnitude of voltages applied to bit lines.

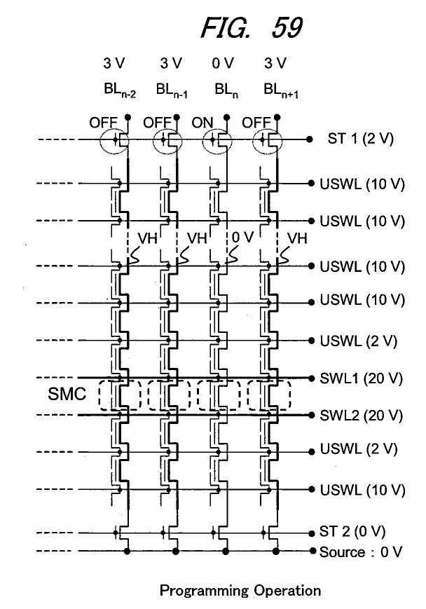

At the time of programming operation, as shown in FIG. 59, about 2 V is applied to the select transistor (ST₁), 0 V is applied to bit line (BLₙ) connected to the selected memory cell (SMC) to which the programming is to be performed, and about 3 V is applied to other bit lines. Further, 0 V is applied to the common source line (CSDL) and the select transistor (ST₂). In this state, the potential of the unselected word line (USWL) is increased rapidly from 0 V to about 10 V (in about several microseconds or less). As a result, the potential of the floating gate 5 below the unselected word line (USWL) is increased, and consequently the potential of the substrate surface below the memory cell is about to increase. At this time, since the select transistor (ST₁) connected to the bit line to which a voltage of about 3 V is applied is in an of f state, the potential of the substrate surface below the memory cell is increased (VH). On the other hand, since the select transistor (ST₁) connected to the bit line (BLₙ) to which 0 V is applied is in an on state, electrons are supplied to the substrate surface below the memory cell from the bit line contract (BLCONT) side, and its potential becomes 0 V.

Subsequently, the potential of the selected word lines (SWL₁, SWL₂) is increased from 0 V to about 20 V. At this time, in the bit line (BLₙ) where the substrate surface potential is 0 V, a large potential difference occurs between the floating gate and the substrate surface, and electrons are injected into the floating gate 5 from the surface of the p-type well 10 by tunnel current, by which the programming occurs. On the other hand, in the bit line where the substrate surface potential is VH, since the potential difference between the floating gate and the substrate surface is decreased, the programming does not occur.

The potential of the unselected word line (USWL) adjacent to the selected word line (SWL₁) and the potential of the unselected word line (USWL) adjacent to the selected word line (SWL₂) are set to about 2 V instead of 10 V. This is because there is a possibility that a programming error in which electrons are injected into the floating gate 5 of the unselected memory cell from the surface of the p-type well 10 may occur if the floating gate potential of the unselected memory cell between the selected word lines (SWL₁, SWL₂) and the adjacent unselected word lines (USWL) becomes too high.

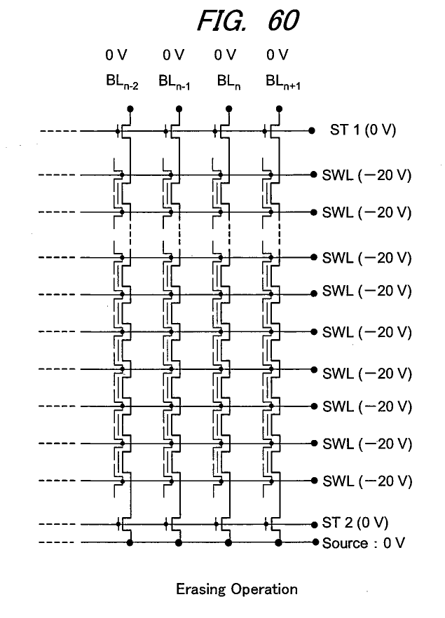

At the time of erasing operation, as shown in FIG. 60, a voltage of about −20 V is applied to all word lines (SWL) between the select transistors (ST₁, ST₂), and electrons are emitted to the substrate 1 from the floating gate 5 by Fowler-Nordheim tunnel current via the gate insulator film 4.

Next, a manufacturing method of the NAND type flash memory will be described with reference to FIG. 61 to FIG. 79. FIG. 61 to FIG. 68 and FIG. 70 to FIG. 79 correspond to sectional views of the principal parts taken along the line A-A and the line B-B in FIG. 53.

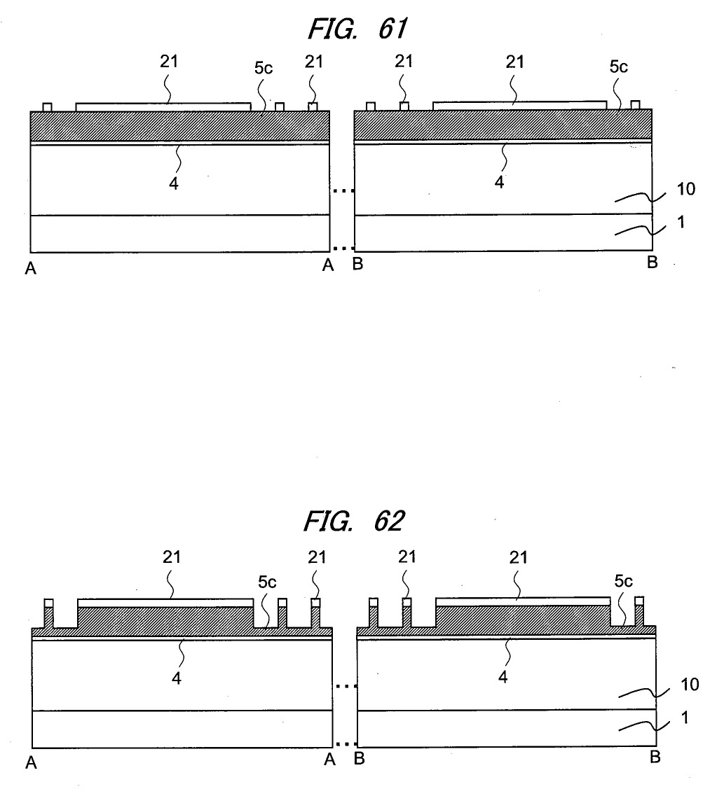

First, as shown in FIG. 61, after a gate insulator film 4 is formed on the surface of the p-type well 10, a polysilicon film 5c doped with phosphorus and a silicon nitride film 21 are deposited on the gate insulator film 4, and the silicon nitride film 21 is patterned. The film thickness of the polysilicon film 5c is about 50 nm, and the film thickness of the silicon nitride film 21 is about 20 nm. Subsequently, as shown in FIG. 62, the polysilicon film 5c is patterned by the dry etching using the silicon nitride film 21 as a mask. This etching is stopped before the underlying gate insulator film 4 is exposed.

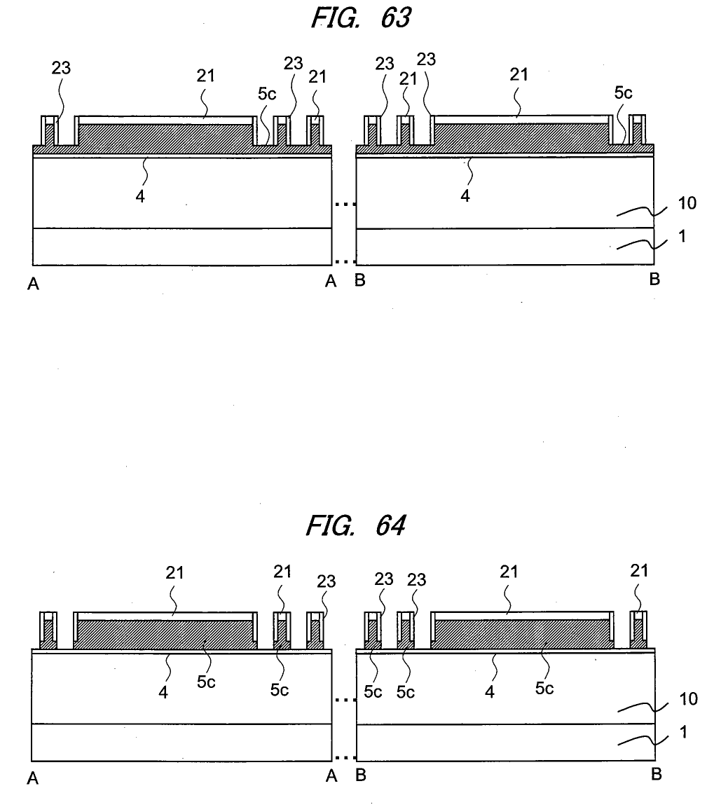

Next, as shown in FIG. 63, a silicon oxide film 23 is deposited by CVD method. The silicon oxide film 23 is deposited to have a small film thickness so that the concave portions of the polysilicon film 5c patterned into a comb shape are not embedded completely. Subsequently, the silicon oxide film 23 is anisotropically dry etched to form silicon oxide films 23 in the shape of sidewalls on the side surfaces of the polysilicon film 5c and the silicon nitride film 21.

Then, as shown in FIG. 64, the polysilicon film 5c is dry-etched using the silicon nitride film 21 and the silicon oxide films 23 formed on its side surface as a mask. By this etching, the polysilicon film 5c is formed to have an inverted T sectional shape, and a plurality of polysilicon films 5c mutually isolated at specific intervals are formed.

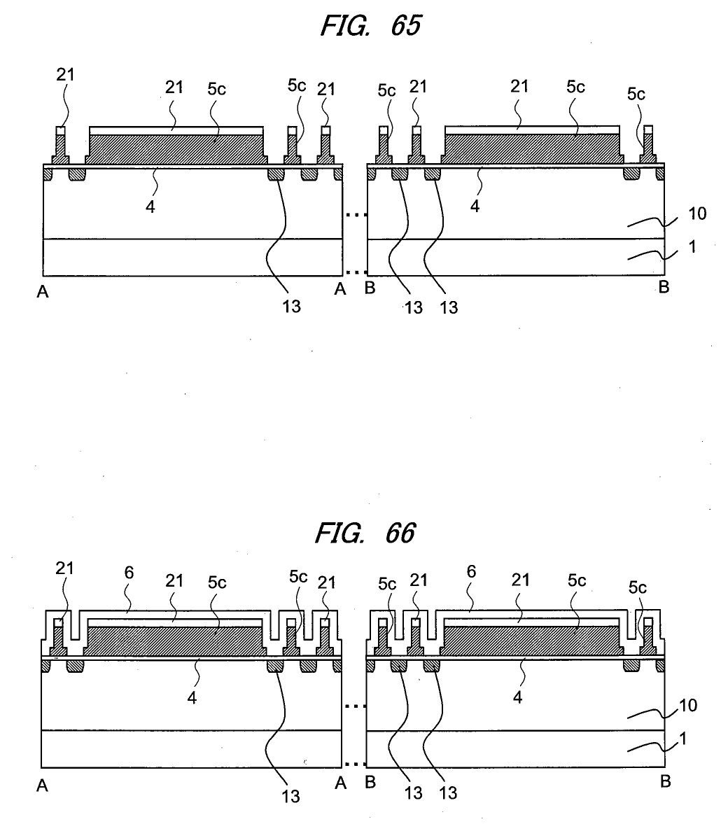

Next, as shown in FIG. 65, after arsenic ions are implanted into the p-type well 10 to form an n-type diffusion layer 11 (source, drain), silicon oxide films 5c formed in the shape of sidewalls are removed by, for example, wet etching. Subsequently, as shown in FIG. 66, a high-K insulator film 6 is deposited by CVD method. The high-K insulator film 6 is formed of a metal oxide film with higher dielectric constant than silicon oxide such as Al₂O₃, HfSiO, or HfO₂. Also, the high-K insulator film 6 is deposited to have a small film thickness so that the gaps between adjacent polysilicon films 5c are not embedded completely. In this embodiment, since the sectional shape of the polysilicon film 5c is an inverted T shape, even if the interval between adjacent polysilicon films 5c is narrowed due to the reduction of memory cell size, the high-K insulator film 6 can be deposited so that the gaps are not embedded completely.

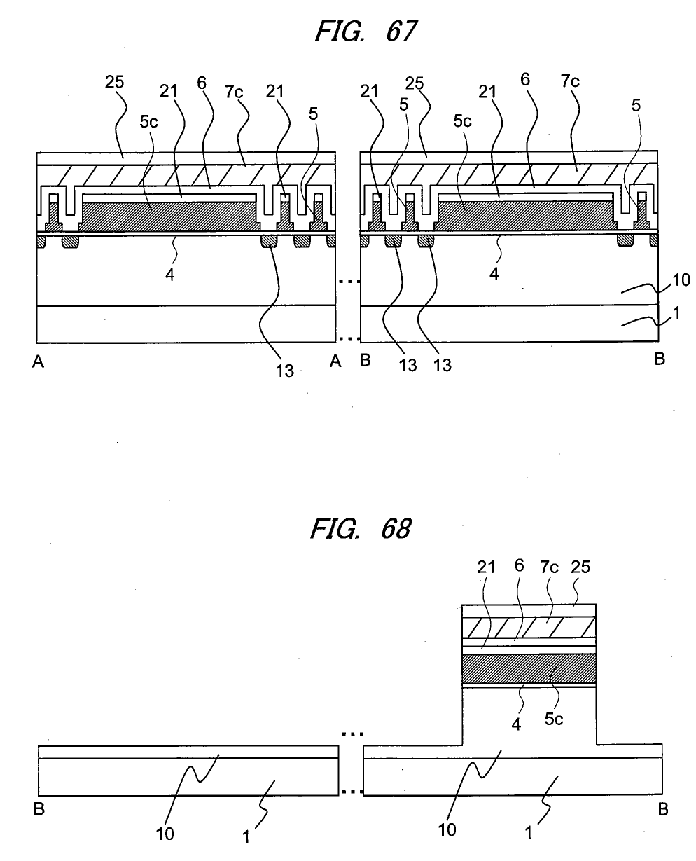

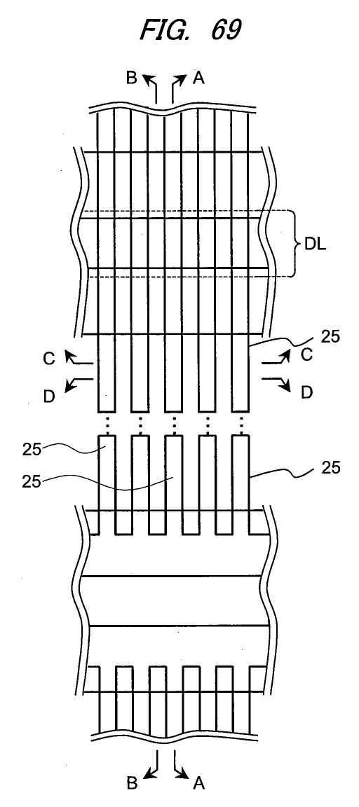

Then, as shown in FIG. 67, a polysilicon film 7c doped with phosphorus and a silicon nitride film 25 are deposited on the high-K insulator film 6 by CVD method. Subsequently, as shown in FIG. 68, the silicon nitride film 25, the polysilicon film 7c, the high-K insulator film 6, the silicon nitride film 21, the polysilicon film 5c, and the gate insulator film 4 in the isolation region are sequentially dry-etched using the photoresist film as a mask. Thereafter, the exposed p-type well 10 is dry-etched to form a plurality of trenches 3b. These trenches 3b have an elongated belt-like planar shape extending in the column direction. Also, by this dry etching, the polysilicon film 5c is isolated for each memory cell, and floating gates 5 are formed. FIG. 69 shows the planar shape of the silicon nitride film 25 patterned by this dry etching.

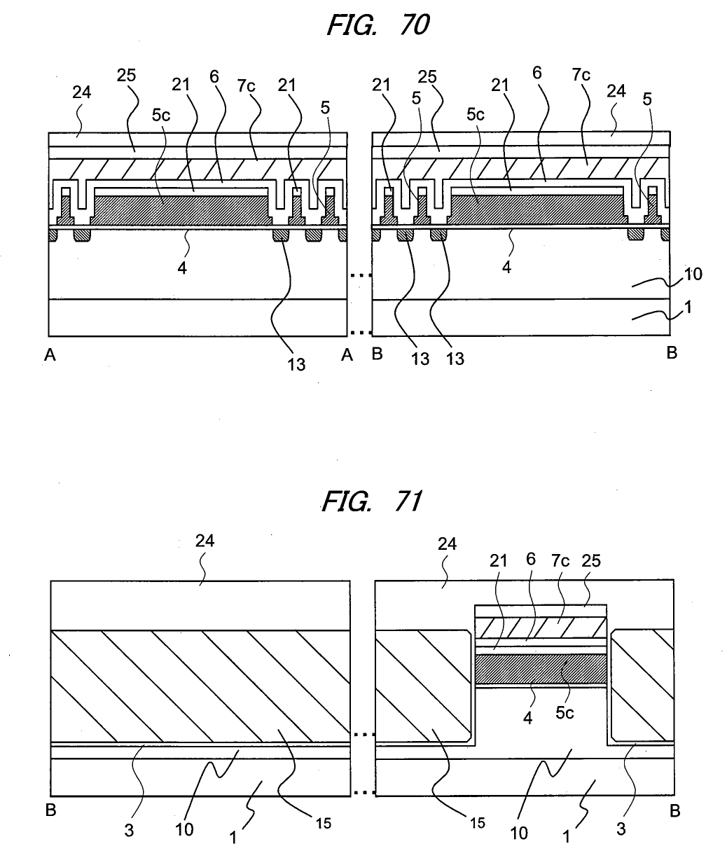

Next, as shown in FIG. 70 and FIG. 71, a silicon oxide film 24 is deposited by CVD method. At this time, similar to the first and second embodiments, the silicon oxide film 24 is embedded incompletely in the trenches 3a so that air gaps 15 are formed therein. The depositing condition is controlled so that the upper end of the air gap 15 is higher than the upper surface of the high-K insulator film 6 and lower than the upper surface of the silicon nitride film 25. Through the process described above, the isolation trenches 3 having an elongated belt-like planar shape extending in a column direction and arrayed at specific intervals in a row direction are completed.

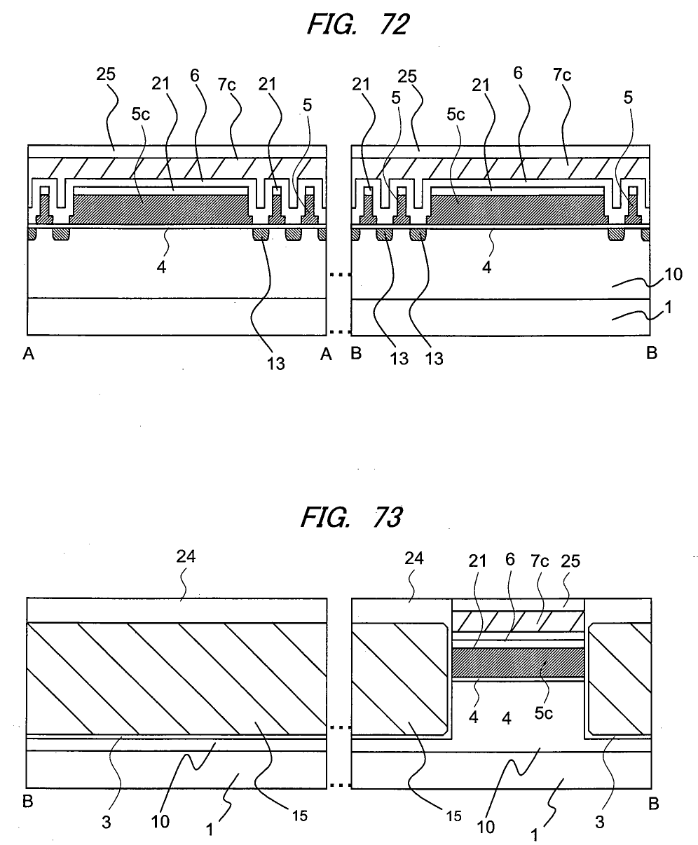

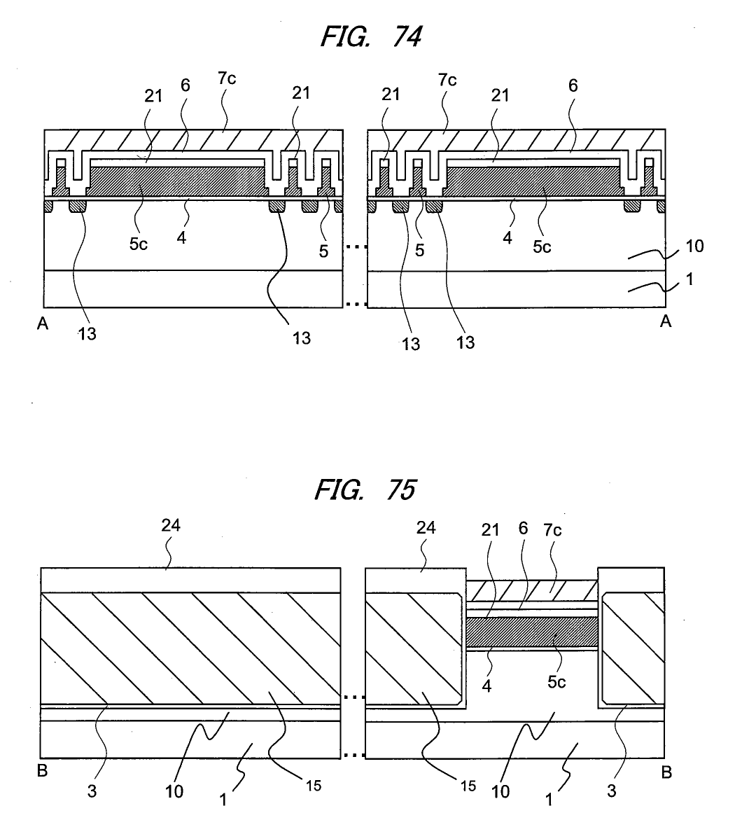

Then, as shown in FIG. 72 and FIG. 73, after the upper surface of the silicon nitride film 25 is exposed by etching back the silicon oxide film 24, as shown in FIG. 74 and FIG. 75, the silicon nitride film 25 is removed by dry etching or wet etching, thereby exposing the upper surface of the polysilicon film 7c.

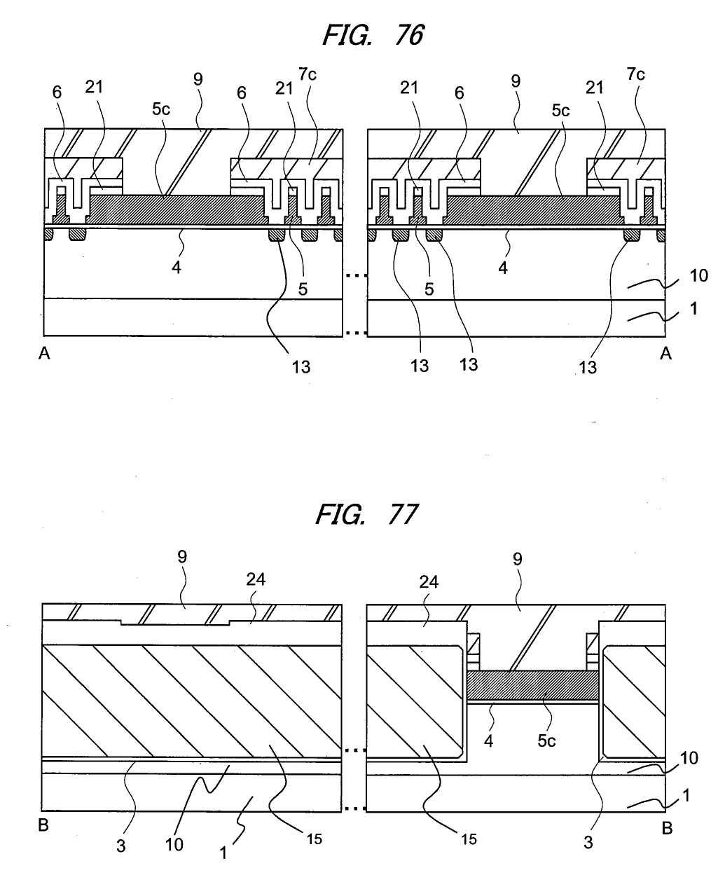

Next, as shown in FIG. 76 and FIG. 77, after the polysilicon film 7c, the high-K insulator film 6, and the silicon nitride film 21 in a region where select transistors (ST₁, ST₂) are formed in a later process are patterned to expose the polysilicon film 5c, a metal film 9 is deposited by sputtering method. The metal film 9 is formed of, for example, a stacked film of tungsten nitride film and a tungsten film or a metal silicide film such as a tungsten silicide film.

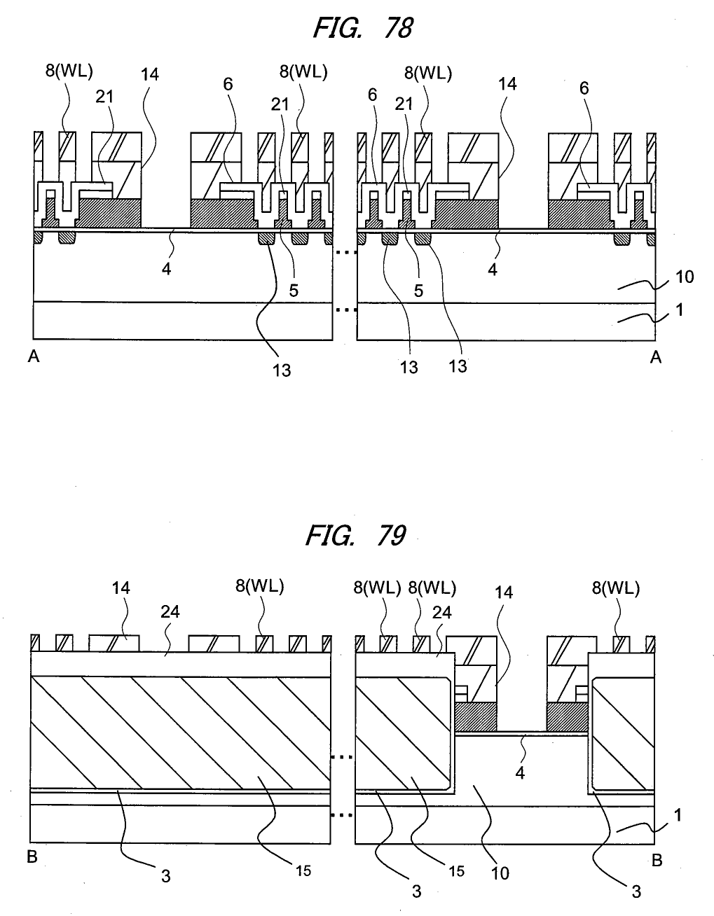

Then, as shown in FIG. 78 and FIG. 79, by dry etching using the photoresist film as a mask, the metal film 9, the polysilicon film 7c and the polysilicon film 5c are sequentially patterned. Through the process described above, a control gate 8 (word line WL) composed of a stacked film of the metal film 9 and the polysilicon film 7c is formed. Further, at the end of the memory array region, gate electrodes 14 of the select transistors (ST₁, ST₂) composed of the stacked film of the metal films 9 and the polysilicon films 7c and 5c are formed. By this dry etching, the high-K insulator film 6 above the floating gate 5 is exposed, but the silicon nitride film 21 is interposed between the floating gate 5 and its upper high-K insulator film 6. Therefore, even if the high-K insulator film 6 above the floating gate 5 is damaged by etching, the reliability of the memory cells is not lowered.

Subsequently, by implanting arsenic ions into the p-type well 10 to form the n-type diffusion layers 11 (BLDL) and the n-type diffusion layer 12 (CSDL), the memory cells and the select transistors (ST₁, ST₂) shown in FIG. 53 to FIG. 57 are completed. Thereafter, though not shown in the drawing, after an interlayer insulator film is formed on the control gate 8 (word line WL), the interlayer insulator film is etched to form contact holes reaching the word lines WL, the p-type well 10, the select transistors (ST₁, ST₂), the n-type diffusion layer 11 (BLDL), and the n-type diffusion layer 12 (CSDL). Then, by forming metal wiring on the interlayer insulator film, the NAND type flash memory of this embodiment is completed.

Similar to the flash memory in the first and second embodiments, in the flash memory of this embodiment, air gaps 15 (specific dielectric constant=about 1.0) with a lower dielectric constant than silicon oxide (specific dielectric constant=about 3.9) are present in the isolation trenches 3 between two floating gates 5 adjacent in a row direction, and the high-K insulator film 6 is isolated between the two floating gates 5. Therefore, similar to the flash memory in the first and second embodiments, even if the memory size is reduced, the threshold voltage shift (ΔVth) due to the capacitance between the floating gates can be suppressed below an allowable value.

Also, similar to the flash memory in the first and second embodiments, since the high-K insulator film 6 is interposed between the floating gate 5 and the control gate 8 in the flash memory of this embodiment, even if the memory size is reduced, it is possible to suppress the decrease of the capacitance between a floating gate and a control gate. In particular, in this embodiment, since the sectional shape of the floating gate 5 is an inverted T shape, it can be expected to increase the capacitance between the control gate and the floating gate by making use of the sidewall of the floating gate 5. Therefore, the coupling ratio can be secured, and high-speed programming/erasing characteristic can be realized.

### Fourth Embodiment

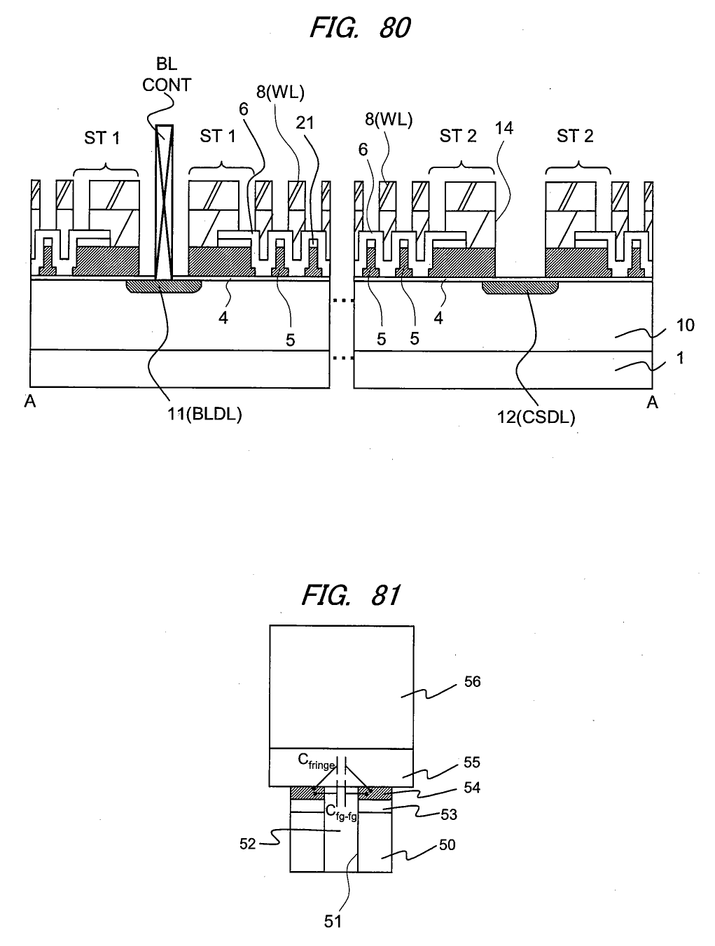

FIG. 80 is a sectional view showing the principal part of a semiconductor device according to a fourth embodiment, and it corresponds to FIG. 54 (sectional view taken along the line A-A) in the third embodiment.

In the flash memory of the third embodiment, n-type diffusion layers 13 (source, drain) of memory cells are formed by implanting impurity ions (arsenic ions) into the p-type well 10. However, in the flash memory of this embodiment, n-type diffusion layers 13 are not formed by implanting impurity ions.

The n-type diffusion layers 13 are formed in order to connect the plurality of memory cells arrayed in a column direction in series. However, the control gate 8 (word line WL) is present between the two floating gates 5 adjacent in the column direction, and a positive potential is applied to the word line WL at the time of reading and programming operations (FIG. 58, FIG. 59). Accordingly, even if the n-type diffusion layers 13 is not provided, the surface of the p-type well 10 positioned between the two floating gates 5 adjacent in the column direction is inverted by the potential of the word line WL. Therefore, the memory cells operate normally even if the n-type diffusion layers 13 are not formed. At the time of erasing operation, since electrons are emitted to the substrate 1 from the floating gate 5, there is no problem if the n-type diffusion layers 13 are not present.

Similar to the flash memory in the first to third embodiments, in the flash memory of this embodiment, air gaps 15 (specific dielectric constant=about 1.0) with a lower dielectric constant than silicon oxide (specific dielectric constant=about 3.9) are present in the isolation trenches 3 between two floating gates 5 adjacent in a row direction, and the high-K insulator film 6 is isolated between the two floating gates 5. Therefore, similar to the flash memory in the first to third embodiments, even if the memory size is reduced, the threshold voltage shift (ΔVth) due to the capacitance between the floating gates can be suppressed below an allowable value.

Also, similar to the flash memory in the first to third embodiments, since the high-K insulator film 6 is interposed between the floating gate 5 and the control gate 8 in the flash memory of this embodiment, even if the memory size is reduced, it is possible to suppress the decrease of the capacitance between a floating gate and a control gate. Therefore, the coupling ratio can be secured, and high-speed programming/erasing characteristic can be realized.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention is applied to a flash memory used in a memory device of a small portable information device such as a mobile personal computer and a digital still camera.

What is claimed is:

1. A semiconductor device comprising a plurality of memory cells disposed in a matrix in a first direction of a main surface of a semiconductor substrate of a first conductivity type and in a second direction orthogonal to the first direction,
wherein each of the plurality of memory cells includes a floating gate formed on the main surface of the semiconductor substrate via a gate insulator film, a first insulator film formed on the floating gate, and a control gate formed on the floating gate via the first insulator film,
the plurality of memory cells arrayed in the first direction are mutually isolated by isolation trenches formed in the main surface of the semiconductor substrate and extending in the second direction,
the plurality of memory cells arrayed in the second direction are connected in series, P1 the control gates of the plurality of memory cells arrayed in the first direction are integrated to form word lines extending in the first direction, and
a second insulator film having an air gap therein is formed in a region where the floating gates adjacent in the first direction are mutually opposed.

2. The semiconductor device according to claim 1,
wherein the first insulator film formed on the floating gate is isolated for each memory cell, and the second insulator film is formed in a region where the first insulator films adjacent in the first direction are mutually opposed.

3. The semiconductor device according to claim 2,
wherein the air gap is also formed in the region where the first insulator films adjacent in the first direction are mutually opposed.

4. The semiconductor device according to claim 1,
wherein the first insulator film is formed of an insulator film with a dielectric constant higher than that of silicon oxide.

5. The semiconductor device according to claim 1,
wherein one end of the plurality of memory cells arrayed in the second direction is connected to a bit line via a first select transistor.

6. The semiconductor device according to claim 5,
wherein the other end of the plurality of memory cells arrayed in the second direction is connected to a common source line via a second select transistor.

7. The semiconductor device according to claim 1,
wherein first semiconductor regions of a second conductivity type constituting drains of the memory cells and second semiconductor regions of the second conductivity type constituting sources of the memory cells are alternately formed along the second direction on the semiconductor substrate between the floating gates adjacent in the second direction, and each of the first semiconductor regions is connected to a bit line via a bit line contact.

8. The semiconductor device according to claim 7,
wherein the second semiconductor regions of the plurality of memory cells arrayed in the first direction are integrated to form common source lines extending in the first direction.

9. The semiconductor device according to claim 1,
wherein a sectional shape of the floating gates along the second direction is an inverted T shape, and a lower end of the control gates is embedded between the floating gates adjacent in the second direction.

10. The semiconductor device according to claim 1,
wherein the semiconductor regions of the second conductivity type constituting the sources and drains of the memory cells are not formed on the semiconductor substrate between the floating gates adjacent in the second direction.

11. A manufacturing method of a semiconductor device comprising a plurality of memory cells disposed in a matrix in a first direction of a main surface of a semiconductor substrate of a first conductivity type and in a second direction orthogonal to the first direction,
wherein each of the plurality of memory cells includes a floating gate formed on the main surface of the semiconductor substrate of the first conductivity type via a gate insulator film, and a control gate formed on the floating gate via the first insulator film,
the plurality of memory cells arrayed in the first direction are mutually isolated by isolation trenches formed in the main surface of the semiconductor substrate and extending in the second direction,
the plurality of memory cells arrayed in the second direction are connected in series,
the control gates of the plurality of memory cells arrayed in the first direction are integrated to form word lines extending in the first direction,
the method comprising:
(a) a step of forming the gate insulator film on the main surface of the semiconductor substrate, and forming a first conductor film, a first insulator film, a second conductor film, and a third insulator film on the gate insulator film;
(b) a step of patterning the third insulator film, the second conductor film, the first insulator film, and the first conductor film, thereby forming a first stacked member which covers the surface of the semiconductor substrate in the memory cell forming region and extends in the second direction and exposing the semiconductor substrate surface in an isolation region;
(c) a step of etching the semiconductor substrate in the isolation region with using the first stacked member as a mask, thereby forming a trench extending in the second direction;
(d) a step of depositing a second insulator film to cover the first stacked member on the semiconductor substrate and embedding the second insulator film incompletely in the trench, thereby forming an isolation trench embedded with the second insulator film having an air gap therein;
(e) after the step (d), etching back the second insulator film to expose an upper surface of the third insulator film, and then removing the third insulator film to expose an upper surface of the second conductor film; and
(f) after the step (e), a step of forming a third conductor film on the semiconductor substrate and patterning the third conductor film, the second conductor film, the first insulator film, and the first conductor film, thereby forming the control gate formed of the third conductor film and the second conductor film and forming the floating gate formed of the first conductor film.

12. The manufacturing method of a semiconductor device according to claim 11,
wherein an upper end of the second insulator film extends above the first insulator film formed on the floating gate, and the air gap is formed in the second insulator film in a region where the floating gates adjacent in the first direction are mutually opposed.

13. The manufacturing method of a semiconductor device according to claim 12,
wherein the air gap is formed in the second insulator film in a region where the first insulator films adjacent in the first direction are mutually opposed.

14. The manufacturing method of a semiconductor device according to claim 11,
wherein the first insulator film is formed of an insulator film with a dielectric constant higher than that of silicon oxide.

15. The manufacturing method of a semiconductor device according to claim 11, further comprising the step of:
after the step (f), implanting impurity ions into the semiconductor substrate in a region between the floating gates adjacent in the second direction, thereby forming a diffusion layer of a second conductivity type for forming a source and a drain of the memory cell.

16. A manufacturing method of a semiconductor device comprising a plurality of memory cells disposed in a matrix in a first direction of a main surface of a semiconductor substrate of a first conductivity type and in a second direction orthogonal to the first direction,
wherein each of the plurality of memory cells includes a floating gate formed on the main surface of the semiconductor substrate of the first conductivity type via a gate insulator film, a control gate formed on the floating gate via a first insulator film, and a diffusion layer of a second conductivity type formed on the main surface of the semiconductor substrate,
the plurality of memory cells arrayed in the first direction are mutually isolated by isolation trenches formed in the main surface of the semiconductor substrate and extending in the second direction,
the plurality of memory cells arrayed in the second direction are connected in series,
the control gates of the plurality of memory cells arrayed in the first direction are integrated to form word lines extending in the first direction,
the method comprising:
(a) a step of forming a first conductor film on the main surface of the semiconductor substrate via the gate insulator film and patterning the first conductor film, thereby forming a plurality of floating gates arrayed at specific interval in the first direction and arrayed at specific interval in the second direction;
(b) a step of etching the semiconductor substrate between the floating gates adjacent in the first direction, thereby forming isolation trenches extending in the second direction;
(c) a step of embedding a second insulator film in the isolation trenches; and
(d) a step of forming a second conductor film on the floating gate via the first insulator film and patterning the second conductor film, thereby forming a plurality of control gates extending in the first direction and arrayed at specific interval in the second direction,
wherein, when embedding the second insulator film in the isolation trenches in the step (c), an air gap is formed in the second insulator film in a region where the floating gates adjacent in the first direction are mutually opposed.

17. The manufacturing method of a semiconductor device according to claim 16,
wherein the step (a) includes a step of patterning a sectional shape of the floating gate along the second direction into an inverted T shape, and
the step (d) includes a step of forming the control gate between the floating gates adjacent in the second direction.
